(19) United States
(12) Patent Application Publication
(10) Pub. No.: US 2008/0035928 A1
(43) Pub. Date: Feb. 14, 2008

(54) Vertical electromechanical memory devices and methods of manufacturing the same

(75) Inventors: Eunjung Yun, Seoul (KR); Sung-Young Lee, Yongin-si (KR); Min-sang Kim, Anyang-Si (KR); Sungmin Kim, Bupyeong-Gu (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/788,011

(22) Filed: Apr. 18, 2007

(30) Foreign Application Priority Data
Aug. 10, 2006 (KR) 10-2006-0075597

(51) Int. Cl. H01L 21/8229; G11C 11/34; H01L 29/10; H01L 21/336

(52) U.S. Cl. 257/67; 257/314; 365/185.01; 438/257; 257/E29.043; 257/E21.613

(57) ABSTRACT

In a memory device and a method of forming a memory device, the device comprises a substrate, a first electrode extending in a vertical direction relative to the substrate, and a second electrode extending in a vertical direction relative to the substrate, the second electrode being spaced apart from the first electrode by a vertical gap. A third electrode is provided that extends in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

### RELATED APPLICATIONS

This application claims priority under 35 U.S.C. 119 to Korean Patent Application No. 10-2006-0075597 filed on Aug. 10, 2006, the content of which is incorporated herein by reference in its entirety.

This application is related to U.S. patent application Ser. No. 11/713,476 filed Mar. 2, 2007, entitled “Electromechanical Memory Devices and Methods of Manufacturing the Same,” by Yun, et al., incorporated herein by reference, and commonly owned with the present application.

This application is further related to U.S. patent application Ser. No. 11/713,770, filed Mar. 2, 2007, entitled “Multi-bit Electromechanical Memory Devices and Methods of Manufacturing the Same,” by Yun, et al., incorporated herein by reference, and commonly owned with the present application.

### BACKGROUND OF THE INVENTION

Semiconductor memory devices include memory cells for the storage of electronic information. Non-volatile memory devices enjoy widespread use because their associated memory cells can retain information even when the source power supply is disabled or removed. This feature makes non-volatile memory devices especially attractive for use in portable electronics. With the continuous trend toward higher integration, high-density layout, low-power operation, and high operating speed are common considerations for such devices.

One type of non-volatile device, referred to as flash memory, has become popular because it is relatively inexpensive to produce, and because it operates at relatively low power demands; however, flash memory is known to generally suffer from low operating speed, relatively poor data retention reliability and relatively short life span. In addition, such devices are based on the operation of conventional transistors, and with the pressures of further integration, they increasingly suffer from the short-channel effect, lowering of breakdown voltage, and lowering of reliability of the gate junction with repeated program/erase cycles. In addition, as the size of the transistor decreases, there is an increased likelihood of intercell interference, which can have a further adverse effect on performance and reliability.

### SUMMARY OF THE INVENTION

Embodiments of the present invention are directed to electromechanical memory devices and methods of manufacture thereof that address and alleviate the above-identified limitations of conventional devices. In particular, embodiments of the present invention provide electromechanical memory devices that realize, among other features, high-density storage, low-voltage program and erase voltages, high-speed operation, enhanced data retention, and high long-term endurance, and methods of formation of such devices. The embodiments of the present invention are applicable to both non-volatile and volatile memory device formats.

In a first aspect, a memory device comprises: a substrate; a first electrode extending in a vertical direction relative to the substrate; a second electrode extending in a vertical direction relative to the substrate, the second electrode being spaced apart from the first electrode by a vertical gap; and a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

In one embodiment, the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

In another embodiment, the first electrode is coupled to a first word line of the device and wherein the second electrode is coupled to a second word line of the device, and wherein the third electrode is coupled to a bit line of the device.

In another embodiment, the first word line comprises a write word line of the device and wherein the second word line comprises a read word line of the device.

In another embodiment, the third electrode comprises an elastically deformable material.

In another embodiment, the third electrode comprises at least one material selected from the group consisting of: gold, silver, copper, aluminum, tungsten, TiN, conductive metal, shaped memory alloy, and nanotubes.

In another embodiment, the first electrode and second electrode each comprise a conductor, and wherein the memory device comprises a volatile memory device.

In another embodiment, the device further comprises a charge trapping structure between the substrate and the first electrode, and wherein the memory device comprises a non-volatile memory device.

In another embodiment, in the first bent position, the third electrode is capacitively coupled to the charge trapping structure of the first electrode.

In another embodiment, the charge trapping structure comprises a structure selected from the group consisting of: an oxide-nitride-oxide (ONO) structure and an oxide-nitride-alumina (ONA) structure.

In another embodiment, the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

In another embodiment, during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

In another embodiment, during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

In another embodiment, during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

In another embodiment, during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

In another aspect, a method of forming a memory device comprises: providing a first electrode extending in a vertical direction relative to a substrate; providing a second electrode extending in a vertical direction relative to the substrate, the second electrode being spaced apart from the first electrode by a vertical gap; and providing a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

In one embodiment, the first and second electrodes are spaced apart from each other by the electrode gap in a first direction, and further comprising providing a dielectric layer adjacent the first and second electrodes in a second direction transverse to the first direction, such that the third electrode is supported by the dielectric layer.

In another embodiment, the method further comprises coupling the first electrode to a first word line of the device, coupling the second electrode to a second word line of the device, and coupling the third electrode to a bit line of the device.

In another embodiment, the first word line comprises a write word line of the device and wherein the second word line comprises a read word line of the device.

In another embodiment, the third electrode comprises an elastically deformable material.

In another embodiment, the third electrode comprises at least one material selected from the group consisting of: gold, silver, copper, aluminum, tungsten, TiN, conductive metal, shaped memory alloy, and nanotubes.

In another embodiment, the first electrode and second electrode each comprise a conductor, and wherein the memory device comprises a volatile memory device.

In another embodiment, the method further comprises providing a charge trapping structure between the substrate and the first electrode, and wherein the memory device comprises a non-volatile memory device.

In another embodiment, in the first bent position, the third electrode is capacitively coupled to the charge trapping structure of the first electrode.

In another embodiment, the charge trapping structure comprises a structure selected from the group consisting of: an oxide-nitride-oxide (ONO) structure and an oxide-nitride-alumina (ONA) structure.

In another embodiment, the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

In another embodiment, during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

In another embodiment, during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

In another embodiment, during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

In another embodiment, during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

In another aspect, a method of forming a memory device comprises: providing a first electrode and a second electrode on a substrate, the first and second electrodes being spaced apart by a gap; providing a sacrificial layer in the gap; providing a third electrode on the sacrificial layer in the gap, the third electrode being spaced apart from the first and second electrodes by the sacrificial layer; and removing the sacrificial layer to form a first gap between the third electrode and the first electrode and to form a second gap between the third electrode and the second electrode.

In one embodiment, the third electrode is elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

In another embodiment, the method further comprises providing a charge trapping structure between the substrate and the first electrode, and wherein the memory device comprises a non-volatile memory device.

In another embodiment, in the first bent position, the third electrode is capacitively coupled to the charge trapping structure of the first electrode.

In another embodiment, the charge trapping structure comprises a structure selected from the group consisting of: an oxide-nitride-oxide (ONO) structure and an oxide-nitride-alumina (ONA) structure.

In another embodiment, the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

In another embodiment, during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

In another embodiment, during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

In another embodiment, during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

In another embodiment, during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

In another embodiment, the method further comprises coupling the first electrode to a first word line of the device, coupling the second electrode to a second word line of the device, and coupling the third electrode to a bit line of the device.

In another embodiment, the first word line comprises a write word line of the device and wherein the second word line comprises a read word line of the device.

In another embodiment, the third electrode comprises an elastically deformable material.

In another embodiment, the third electrode comprises at least one material selected from the group consisting of: gold, silver, copper, aluminum, tungsten, TiN, conductive metal, shaped memory alloy, and nanotubes.

In another embodiment, the first electrode and second electrode each comprise a conductor, and wherein the memory device comprises a volatile memory device.

In another embodiment, providing the first electrode and the second electrode on the substrate comprises: providing an electrode layer on the substrate; providing a dielectric layer on the substrate adjacent the first electrode layer; and providing a first opening in the first electrode layer to form a first electrode and a second electrode spaced apart by the gap, and wherein the third electrode is supported by the dielectric layer.

In another embodiment, providing the sacrificial layer in the gap reduces the width of the gap, and wherein providing the third electrode on the sacrificial layer in the gap provides the third electrode in the opening having the reduced width so that when the sacrificial layer is removed, the third electrode is spaced apart from the first and second electrodes by the respective first and second gaps.

In another aspect, a stacked memory device comprises: a first device layer including an array of transistor devices; and a second device layer including an array of memory cells, the first and second device layers being vertically arranged with respect to each other, wherein the memory cells of the first array each include: a first electrode extending in a vertical direction relative to the substrate; a second electrode extending in a vertical direction relative to the substrate, the second electrode being spaced apart from the first electrode by a vertical gap; and a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

In one embodiment, in each of the memory cells, the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

In another embodiment, in each of the memory cells, the first electrode is coupled to a first word line of the device and wherein the second electrode is coupled to a second word line of the device, and wherein the third electrode is coupled to a bit line of the device.

In another embodiment, in each of the memory cells, the first word line comprises a write word line of the device and wherein the second word line comprises a read word line of the device.

In another embodiment, in each of the memory cells, the third electrode comprises an elastically deformable material.

In another embodiment, in each of the memory cells, the third electrode comprises at least one material selected from the group consisting of: gold, silver, copper, aluminum, tungsten, TiN, conductive metal, shaped memory alloy, and nanotubes.

In another embodiment, in each of the memory cells, the first electrode and second electrode each comprise a conductor, and wherein the memory cell comprises a volatile memory device.

In another embodiment, each of the memory cells further comprises a charge trapping structure between the substrate and the first electrode, and wherein the memory cells each comprise a non-volatile memory device.

In another embodiment, in each of the memory cells, in the first bent position, the third electrode is capacitively coupled to the charge trapping structure of the first electrode.

In another embodiment, in each of the memory cells, the charge trapping structure comprises a structure selected from the group consisting of: an oxide-nitride-oxide (ONO) structure and an oxide-nitride-alumina (ONA) structure.

In another embodiment, in each of the memory cells, the first electrode comprises a write electrode and wherein the second electrode comprises a read electrode, and wherein, during a write operation of the memory cell, the third electrode is placed in one of the bent position in contact with the write electrode and the rest position, by applying a first voltage potential between the write electrode and the third electrode.

In another embodiment, in each of the memory cells, during a write operation of a first state of the memory cell that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

In another embodiment, in each of the memory cells, during a read operation of the memory cell in the first state, a second voltage potential is applied between the third electrode and the read electrode, and wherein the read operation results in the determination of the first state when the third electrode remains in the bent position in contact with the write electrode, despite application of the second voltage potential.

In another embodiment, in each of the memory cells, during a write operation of a second state of the memory cell that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

In another embodiment, in each of the memory cells, during a read operation of the memory cell in the second state, a second voltage potential is applied between the third electrode and the read electrode, and wherein the read operation results in the determination of the second state when the third electrode is placed in a bent position in contact with the read electrode as a result of the applied second voltage potential.

In another embodiment, the memory cells of the array are non-volatile memory cells.

In another embodiment, the memory cells of the array are volatile memory cells.

In another aspect, a non-volatile memory device comprises: a substrate; a first charge trapping structure on the substrate; a first electrode on the first charge trapping structure extending in a vertical direction relative to the substrate; a second electrode extending in a vertical direction relative to the substrate, the second electrode being spaced apart from the first electrode by a vertical gap; and a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

In another embodiment, the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

In another embodiment, the first electrode is coupled to a first word line of the device and wherein the second electrode is coupled to a second word line of the device, and wherein the third electrode is coupled to a bit line of the device.

In another embodiment, the first word line comprises a write word line of the device and wherein the second word line comprises a read word line of the device.

In another embodiment, the third electrode comprises an elastically deformable material.

In another embodiment, the third electrode comprises at least one material selected from the group consisting of: gold, silver, copper, aluminum, tungsten, TiN, conductive metal, shaped memory alloy, and nanotubes.

In another embodiment, the first electrode and second electrode each comprise a conductor.

In another embodiment, the device further comprises a second charge trapping structure between the substrate and the second electrode.

In another embodiment, in the first bent position, the third electrode is capacitively coupled to the charge trapping structure of the first electrode.

In another embodiment, the charge trapping structure comprises a structure selected from the group consisting of: an oxide-nitride-oxide (ONO) structure and an oxide-nitride-alumina (ONA) structure.

In another embodiment, the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

In another embodiment, during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

In another embodiment, during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

In another embodiment, during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

In another embodiment, during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

In another aspect, a memory device comprises: a plurality of memory devices, each memory device comprising: a write electrode extending in a vertical direction relative to the substrate; a read electrode extending in a vertical direction relative to the substrate, the read electrode being spaced apart from the write electrode by a vertical gap; and a transition electrode extending in a vertical direction in the electrode gap, the transition electrode being spaced apart from the write electrode by a first gap and the transition electrode being spaced apart from the read electrode by a second gap, the transition electrode being elastically deformable such that the transition electrode deflects to be electrically coupled with the write electrode through the first gap in a first bent position and to be electrically coupled with the read electrode through the second gap in a second bent position, and to be isolated from the write electrode and the read electrode in a rest position. In the memory device, the plurality of memory devices are arranged in an array along multiple rows in a row direction and along multiple columns in a column direction on the substrate. A plurality of bit lines extend in the column direction, the transition electrodes of the memory devices of a same column being coupled to a same one of the bit lines. A plurality of write word lines extend in the row direction, the write electrodes of the memory devices of a same row being coupled to a same one of the write word lines. A plurality of read word lines extend in the row direction, the read electrodes of the memory devices of a same row being coupled to a same one of the read word lines.

In one embodiment, the write and read electrodes are spaced apart from each other by the electrode gap in a first direction, and further comprising a dielectric layer adjacent the write and read electrodes in a second direction transverse to the first direction, and wherein the transition electrode is supported by the dielectric layer.

In another embodiment, the transition electrodes comprise an elastically deformable material.

In another embodiment, the transition electrodes comprise at least one material selected from the group consisting of: gold, silver, copper, aluminum, tungsten, TiN, conductive metal, shaped memory alloy, and nanotubes.

In another embodiment, the write electrodes and read electrodes each comprise a conductor, and wherein the memory device comprises a volatile memory device.

In another embodiment, the memory device further comprises charge trapping structure between the substrate and the write electrodes, and wherein the memory device comprises a non-volatile memory device.

In another embodiment, in the first bent position, the transition electrodes are capacitively coupled to the charge trapping structures of the first electrodes.

In another embodiment, the charge trapping structures comprise a structure selected from the group consisting of: an oxide-nitride-oxide (ONO) structure and an oxide-nitride-alumina (ONA) structure.

In another embodiment, during a write operation of the memory device, the transition electrode is placed in one of the bent position in contact with the write electrode and the rest position, by applying a first voltage potential between the write electrode and the transition electrode.

In another embodiment, during a write operation of a first state of the memory device that results in the transition electrode being placed in a bent position in contact with the write electrode, the transition electrode bends to make contact with the write electrode in the bent position in response to the first voltage potential between the write electrode and the transition electrode, and wherein, when the first voltage potential between the write electrode and the transition electrode is removed, the transition electrode remains in the bent position as a result of charge that is trapped in the charge trapping structure of the write electrode.

In another embodiment, during a read operation of the memory device in the first state, a second voltage potential is applied between the transition electrode and the read electrode, and wherein the read operation results in the determination of the first state when the transition electrode remains in the bent position in contact with the write electrode, despite application of the second voltage potential.

In another embodiment, during a write operation of a second state of the memory device that results in the transition electrode being placed in the rest position, the transition electrode is isolated from the write electrode in the rest position in response to the first voltage potential between the write electrode and the transition electrode, and wherein, when the first voltage potential between the write electrode and the transition electrode is removed, the transition electrode remains in the rest position.

In another embodiment, during a read operation of the memory device in the second state, a second voltage potential is applied between the transition electrode and the read electrode, and wherein the read operation results in the determination of the second state when the transition electrode is placed in a bent position in contact with the read electrode as a result of the applied second voltage potential.

### BRIEF DESCRIPTION OF THE DRAWINGS

The foregoing and other objects, features and advantages of the embodiments of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention. In the drawings:

FIG. 1 is a cross-sectional view of an illustrative embodiment of a conventional type of memory device that utilizes electromechanical interaction for programming the state of the device;

FIG. 2 is a perspective view of a volatile electromechanical memory device in accordance with an embodiment of the present invention;

FIG. 3A is an example chart of applied voltages for performing programming, write, erase and read operations of the unit memory cell embodiments of FIGS. 2 and 7; FIG. 3B is a graph of the state of the transition electrode as a function of the applied voltage difference between voltage levels applied to the bit line V_{BL} and the write word line V_{WWL};

FIGS. 4A and 4B are perspective views of a memory cell in a first state and a read operation of the memory cell in the first state, for the volatile electromechanical memory device embodiment of FIG. 2;

FIGS. 5A and 5B are perspective views of a memory cell in a second state and a read operation of the memory cell in the second state, for the volatile electromechanical memory device embodiment of FIG. 2;

FIGS. 6A-6I are perspective views of a method for forming a volatile electromechanical memory device in accordance with an embodiment of the present invention;

FIG. 7 is a perspective view of a non-volatile electromechanical memory device in accordance with an embodiment of the present invention;

FIGS. 8A and 8B are perspective views of a memory cell in a first state and a read operation of the memory cell in the first state, for the non-volatile electromechanical memory device embodiment of FIG. 7;

FIGS. 9A and 9B are perspective views of a memory cell in a second state and a read operation of the memory cell in the second state, for the non-volatile electromechanical memory device embodiment of FIG. 7;

FIG. 10 is a perspective view of a method for forming a non-volatile electromechanical memory device, in accordance with an embodiment of the present invention;

FIG. 11 is a perspective sectional view of a stacked memory device wherein a layer of devices are formed on an device layer that lies below a layer including electromechanical memory cells, in accordance with an embodiment of the present invention;

FIG. 12 is a perspective view of a non-volatile electromechanical memory device array in accordance with an embodiment of the present invention;

FIGS. 13A-13E are perspective views of a method for forming the non-volatile electromechanical memory device array of FIG. 12, in accordance with an embodiment of the present invention; and

FIG. 14 is a perspective view of memory cells of the non-volatile electromechanical memory device array of FIG. 12 written to contain state information, in accordance with an embodiment of the present invention.

### DETAILED DESCRIPTION OF EMBODIMENTS OF THE INVENTION

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Like numbers refer to like elements throughout the specification.

It will be understood that, although the terms first, second, etc. are used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). When an element is referred to herein as being “over” another element, it can be over or under the other element, and either directly coupled to the other element, or intervening elements may be present, or the elements may be spaced apart by a void or gap. As used herein, the term “word line structure” can include a conductive word line itself, or a conductive word line and corresponding charge trapping structure, or additional structures or components that are associated with the word line.

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

The term “transverse”, as used herein, when referring to the first and second directions of extension of the various components, refers to relative directions of extension that are other than parallel to each other, and includes, for example, any angle, including 90 degrees, with respect to each other.

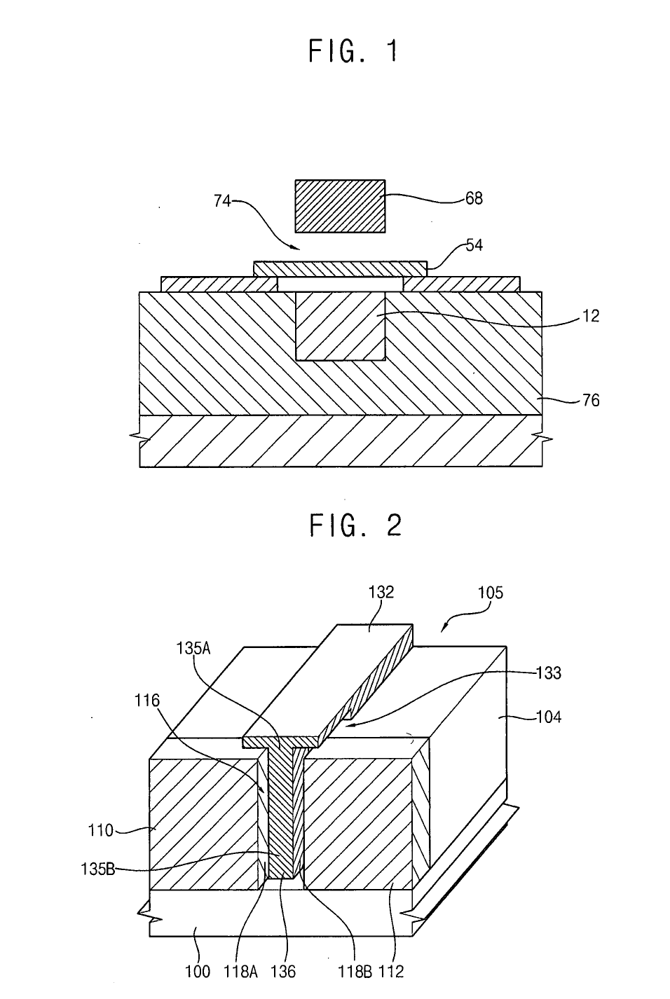

Next-generation, emerging technologies are under development in an effort to address the limitations associated with contemporary flash memory platforms. One such design is disclosed by Jaiprakash, et al., United States Patent Application Publication 2004/0181630, the content of which is incorporated herein by reference. FIG. 1 is a cross-sectional view of an illustrative embodiment of the type of device disclosed in the Jaiprakash, et al. reference.

With reference to FIG. 1, this system relies on a flexible fabric 54 that operates as a mechanical switch that is suspended in the gaps 74 between first and second electrodes 68, 12. The position of the fabric 54 relative to the electrodes 68, 12 is programmable to provide data states, so that the device is operable as a switch. The flexible fabric 54 is formed of a carbon nanotube material, which is expensive to produce, and the accurate placement of which in a semiconductor manufacturing process is difficult to control. In addition, this device is not readily manufacturable in a dense array of cells; therefore, its application to low-cost, high-density semiconductor devices is somewhat limited.

Embodiments of the present invention as illustrated herein provide electromechanical memory devices that provide, among other features, high-density storage, low-voltage program and erase voltages, high-speed operation, enhanced data retention, and high longevity, and methods of formation of such devices. Data retention is ensured by Coulomb forces, rather than through electron tunneling. This leads to enhanced longevity and longer, and more reliable, data retention. In addition, further integration of the devices is not limited by the short-channel effect or by lowering of breakdown voltage. Also, device longevity is maintained through repeated program/erase cycles, since such cycles are not dependent on the properties of gate insulator materials. In addition, intercell interference is mitigated or eliminated because cell data status is determined mechanically, rather than electrically. A relatively simple manufacturing process can be used to form the devices, using standard fabrication techniques.

FIG. 2 is a perspective view of a volatile electromechanical memory device in accordance with an embodiment of the present invention.

With reference to FIG. 2, a unit memory cell 105 includes a first electrode 110 referred to herein as a “write electrode”, a second electrode 112 referred to herein as a “read electrode” and a third electrode 136 referred to herein as a “transition electrode”. The write electrode 110 and read electrode 112 are positioned on a substrate 100, and are each insulated from the substrate 100 by a first insulating layer 101. The write electrode 110 and read electrode 112 are spaced apart from each other by a trench 116 formed between them.

A second insulating layer 104 is disposed at back sides of the write and read electrodes 110, 112, and a conductive transition electrode terminal 132 is positioned on the second insulating layer 104. The transition electrode terminal 132 is suspended over the trench 116, and is isolated from the write and read electrodes 110, 112 by a recess 133 formed in the transition electrode terminal 132 between an underside of the transition electrode terminal 132 and top surfaces of the write and read electrodes 110, 112.

The transition electrode 136 is suspended in the trench 116 between the write electrode 110 and read electrode 112, and is spaced apart from the write electrode 110 in a horizontal direction by a first gap 118A and spaced apart from the read electrode 112 in a horizontal direction by a second gap 118B. The transition electrode 136 includes a first end 135A that is anchored to, and electrically coupled to, an underside of the transition electrode terminal 132, and includes a second end 135B that is suspended in the trench 116, between the write and read electrodes 110, 112.

In the illustrative embodiment of FIG. 2, the memory cell 105 can be incorporated in a memory cell array of a memory device in which the write electrode 110 is coupled to a write word line of the device, the read electrode 112 is coupled to a read word line of the device and the transition electrode 136 and corresponding transition electrode terminal 132 are coupled to a bit line of the device. Rows of bit lines extend in a first direction on the substrate and columns of read and write word lines extend in a second direction on the substrate, the second direction of extension being transverse to the first direction of extension. In this manner, the bit lines and write and read word lines intersect each other, and each intersection point corresponds with a memory cell 105 of the device.

In one embodiment, unit memory cells 105 neighboring each other in the second direction of extension share a common read word line and write word line, and unit memory cells 105 neighboring each other in the first direction of extension share a common bit line.

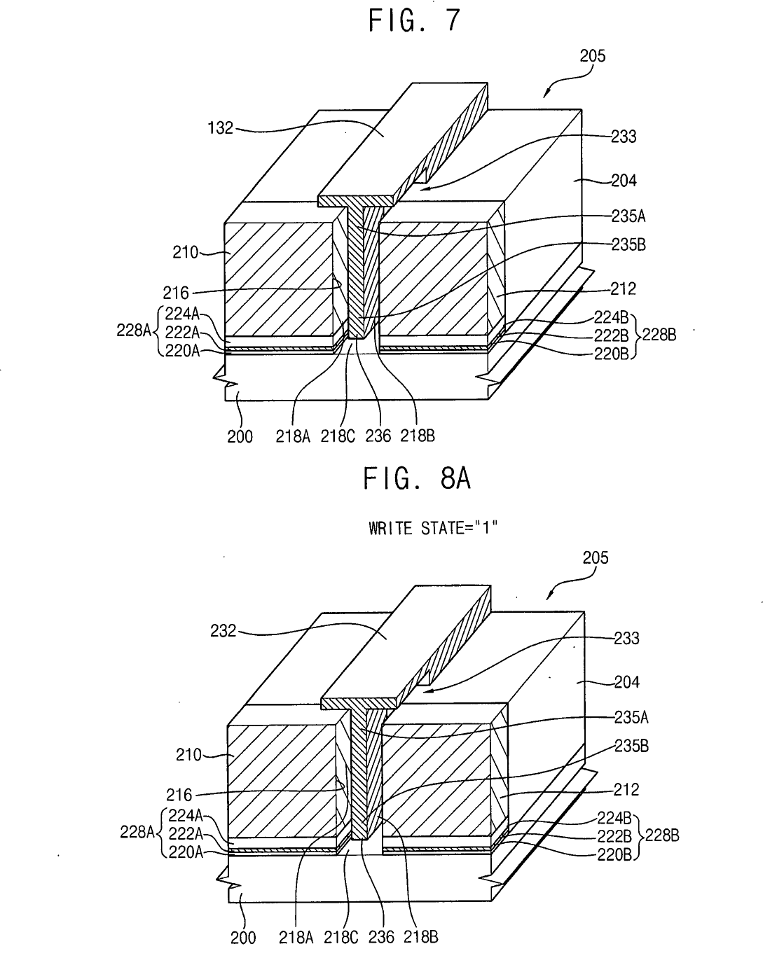

In the embodiment depicted in FIG. 2, the transition electrode 136 is suspended in position between the first and second gaps 118A, 118B, between the write electrode 110 and the read electrode 112, and is formed of an elastically deformable material so as to be movable through the first and second gaps 118A, 118B. By controlling the position of the transition electrode 136 in the gaps 118A, 118B, the transition electrode 136 can be caused to make contact, for example, in an engaged position, with a side surface of the write electrode 110 or with a side surface of the read electrode 112, or can be made to be suspended, for example, in a rest position, between the write and read electrodes 110, 112 and not make contact with either. By controlling the respective voltage levels of the voltages applied to the bit line connected to the transition electrode 136, and applied to the independent write and read word lines connected respectively to the write and read electrodes 110, 112, write and read operations of each of the memory cells 105 can be performed on the volatile electromechanical memory cell embodiment depicted in FIG. 2, and program, erase, write and read operations of each of the memory cells 105 can be performed on the non-volatile electromechanical memory cell embodiment depicted in FIG. 7, as will be described in detail below. For example, by applying a suitable voltage level to the write word line connected to the write electrode 110, by applying a suitable voltage level to the read word line connected to the read electrode 112, and by applying a suitable voltage to the bit line connected to the transition electrode terminal 132, the state of the memory cell 105 can be written to a “1” state or to a “0” state. Later, by applying suitable voltage levels to the bit line connected to the transition electrode 136 and the read word line connected to the read electrode 112, a read operation of the state of the memory cell 105 can be performed, as will be described in detail below.

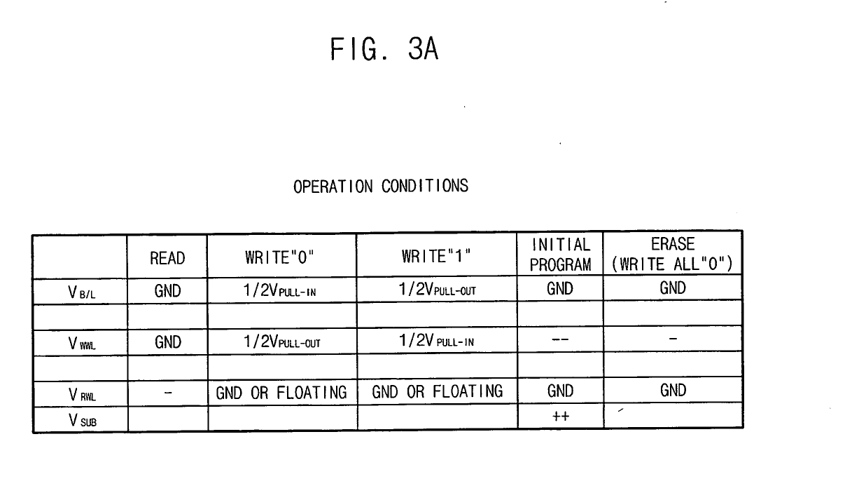

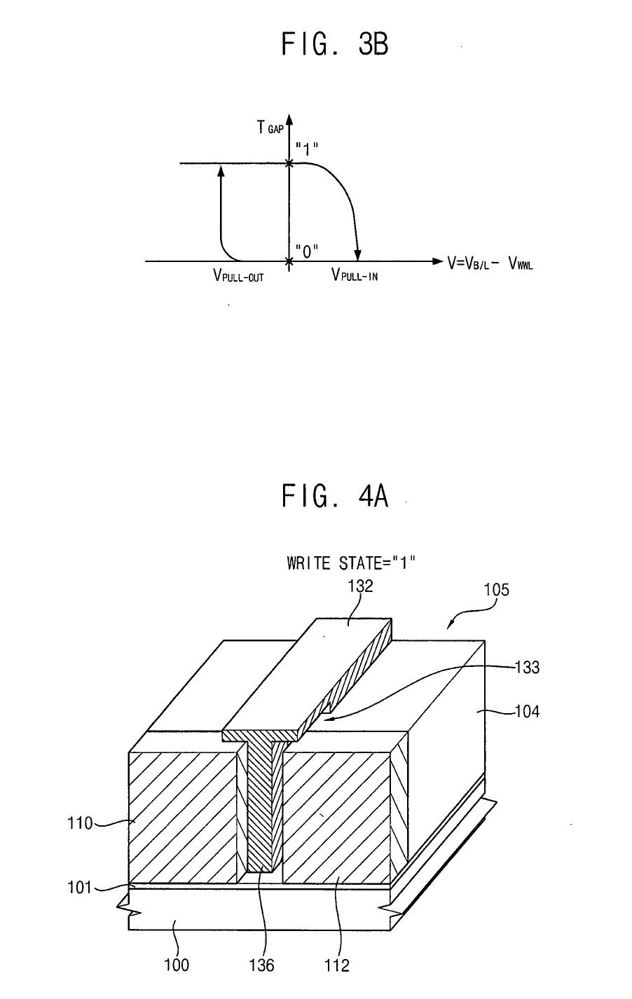

FIG. 3A is an example chart of applied voltages for performing read, write, programming, and erase operations of the unit memory cell embodiment of FIGS. 2 and 7, or the device array embodiment of FIG. 12. FIG. 3B is a graph of the state of the transition electrode 236 as a function of the applied voltage difference between voltage levels applied to the bit line V_{BL} and the write word line V_{WWL} for the non-volatile memory cell embodiment of FIG. 7.

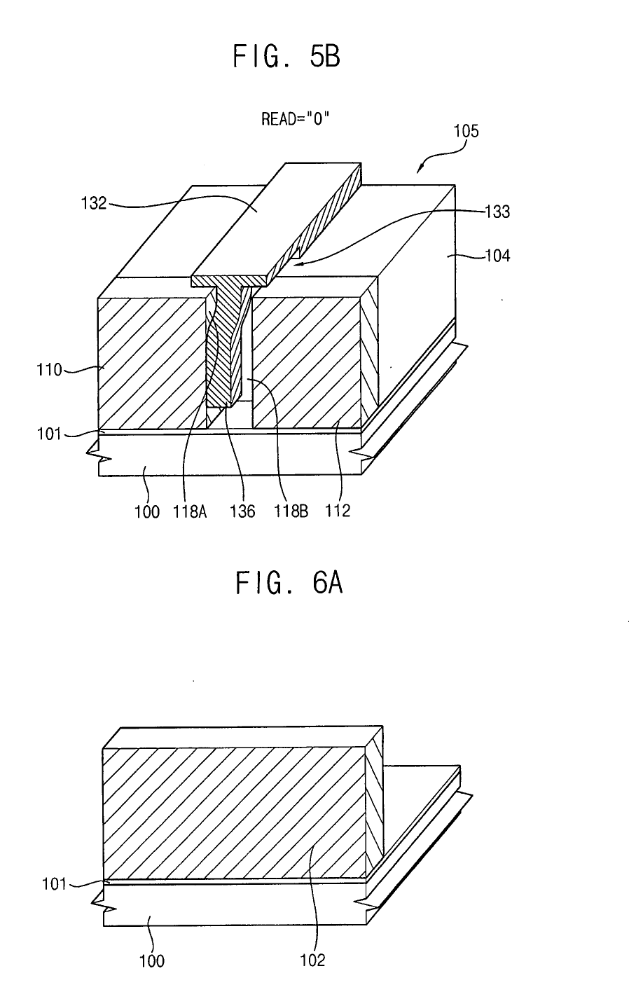

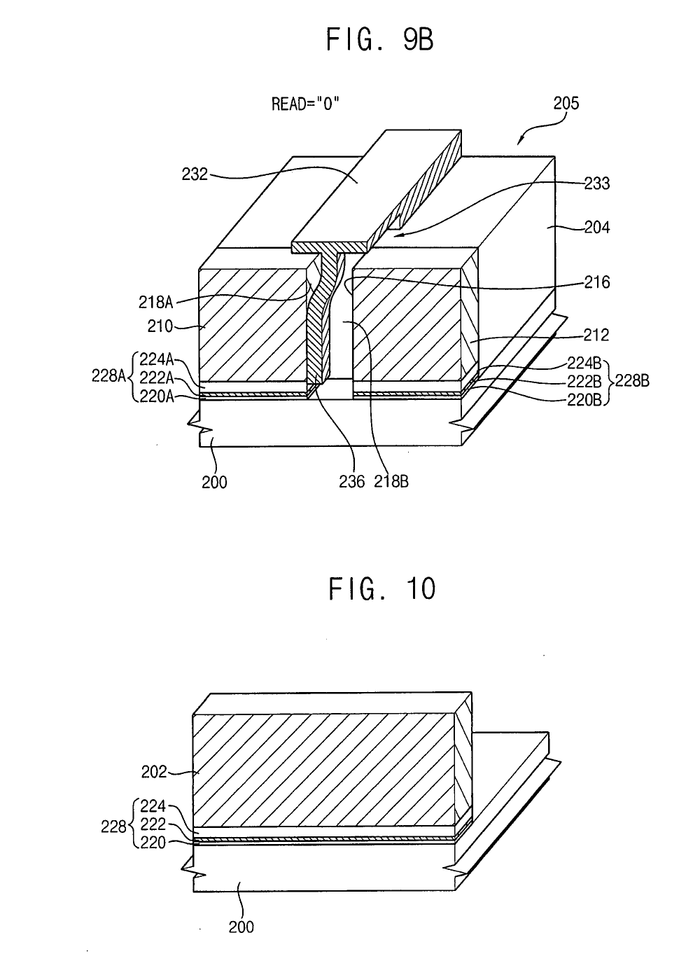

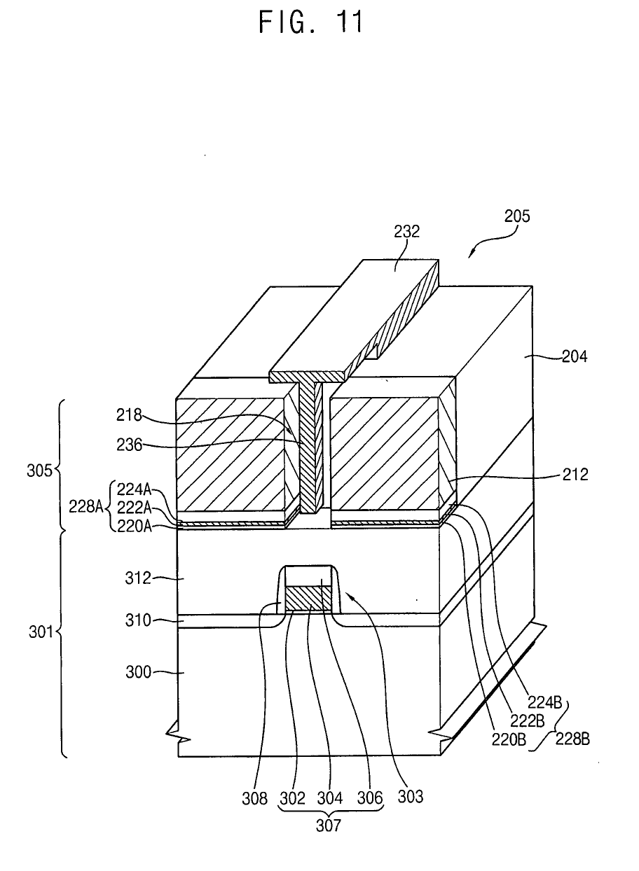

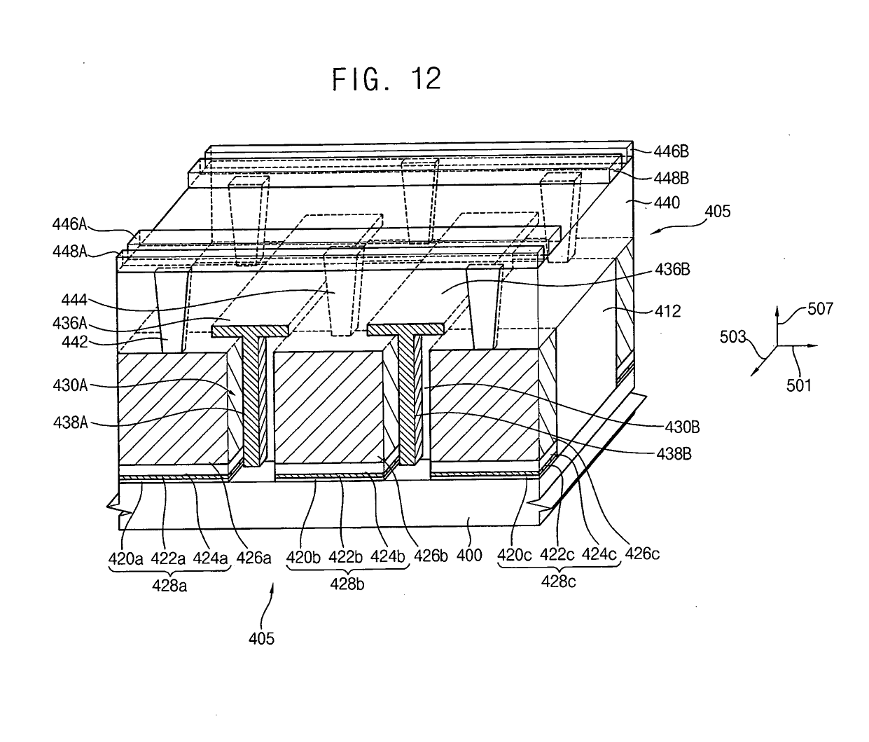

With reference to FIG. 3A, in the case of the writing of a “0” state, the transition electrode 136, 236 is placed in a position of contact with the write electrode 110, 210. This state is shown in FIGS. 5A and 9A, which are described below. To enable this, the voltage differential between the bit line V_{BL} coupled to the transition electrode 136, 236 and the write word line V_{WWL} coupled to the write electrode 110, 210 is made to be a positive value. For example, V_{BL}=2V and V_{WWL}=−2V. Other lines, including the selected read word line coupled to the read electrode 112, 212, and any unselected bit lines and read and write word lines are placed in a ground or floating state. The threshold voltage of the pull-in state is 4 volts in this example, where “pull-in” refers to a position of the transition electrode 136, 236 whereby the transition electrode 136, 236 is in contact with the write electrode 110, 210.

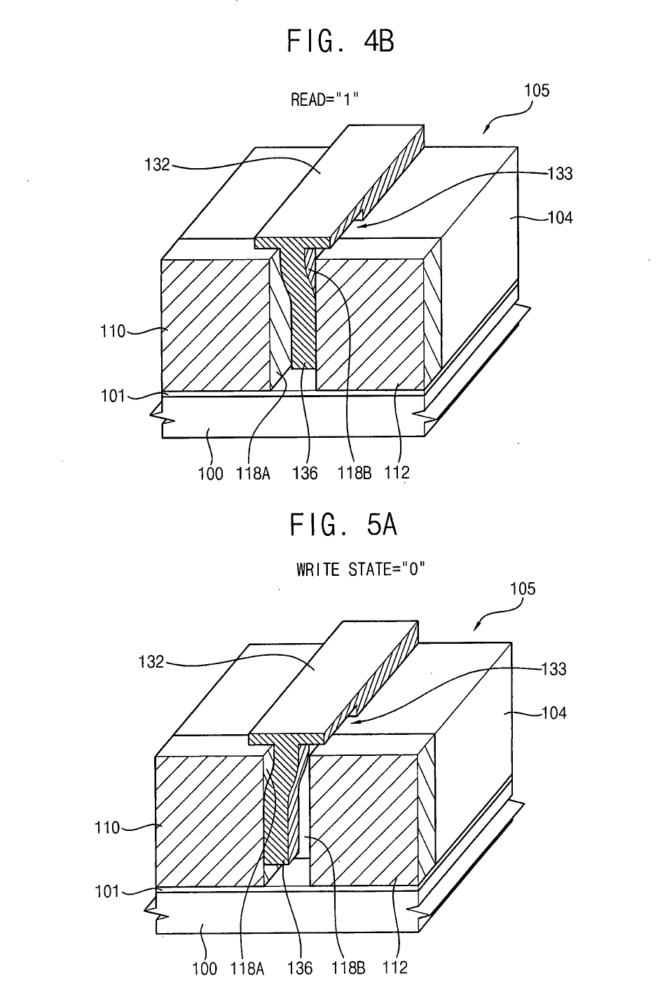

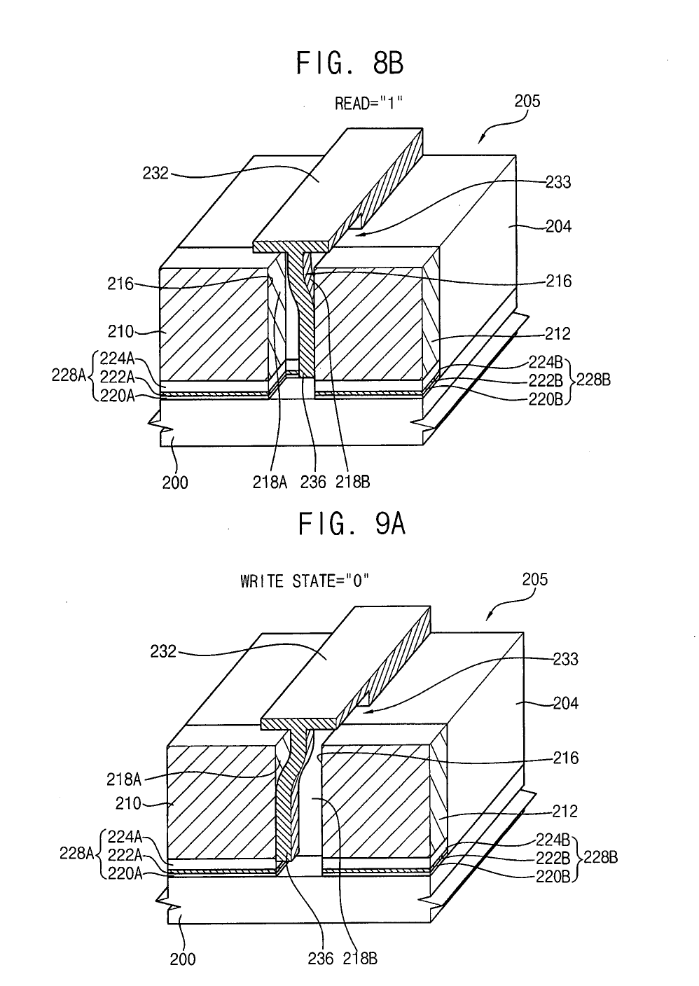

In the case of the writing of a “1” state, the transition electrode 136, 236 is placed in a position of suspension in the gaps 118A, 118B, 218A, 218B between the write electrode 110, 210 and the read electrode 112, 212. This state is shown in FIGS. 4A and 8A, which are described below. To enable this, the voltage differential between the bit line V_{BL} coupled to the transition electrode 136, 236 and the selected write word line V_{WWL} coupled to the write electrode 110, 210 is made to be a small positive, or small negative, value. For example, V_{BL}=−2V and V_{WWL}=0V. Other lines, including the selected read word line coupled to the read electrode 112, 212, and any unselected bit lines and read and write word lines are placed in a ground or floating state. In this case, the direction of the applied electrostatic force is in a direction from the write electrode 110, 210 to the transition electrode 136, 236, which restores the transition electrode 50 from its former position, which can include a position in contact with the write electrode 110, 210, to a state of suspension in the gaps 118A, 118B, 218A, 218B between the write electrode 110, 210 and the read electrode 112, 212. The restoring force of the applied electrostatic force thus overcomes the electrostatic force, or Coulomb force, between the transition electrode 136, 236 coupled to the selected bit line and the write electrode 110, 210 of the selected write word line.

A programming operation is applicable to the non-volatile electromechanical memory cell embodiment of FIGS. 7-10. In the case of a programming operation, all memory cells 205 are placed in a state of “0”, that is, all transition electrodes 236 in the device are placed in a position of contact with the corresponding write electrode 210. To enable this, the voltage differential between the substrate V_{SUB} and all write word lines V_{WWL} is made to be a large positive value. For example, V_{SUB}=10V and V_{WWL}=−10V. In this manner, the applied electrostatic force causes electrons to be trapped in the charge trapping layers 222A of the corresponding charge trapping structure 228A, the transition electrodes 236 is retained in the bent position by the attractive force between the transition electrode 236 and the charge trapping structure 228A that lies below the write electrode 210. Referring to the chart of FIG. 3A, in this example, during the programming operation, the voltage of the substrate V_{SUB} is set to a large positive value, represented by “++”, the voltage of the write word line V_{WWL} coupled to the write electrode 210 is set to a large negative value, represented by “−−”, and the voltage of the read word line V_{RWL} coupled to the read electrode 212, and the voltage of the bit line V_{B/L} coupled to the transition electrode 236, are set to an intermediate value, such as a ground voltage GND.

An erase operation is applicable to the non-volatile electromechanical memory cell embodiment of FIGS. 7-10. In the case of an erase operation, all memory cells 205 are placed in a state of “0”, that is, all transition electrodes 236 in the device are placed in a position of contact with the corresponding write electrode 210. To enable this, the voltage differential between all write word lines V_{WWL} and the bit lines V_{BL} is made to be a negative value. For example, V_{BL}=GND, V_{RWL}=GND and V_{WWL}=“−”, where “−” represents a moderate negative voltage. In this manner, the applied electrostatic force causes the transition electrodes 236 to come into contact with the corresponding write electrodes 210.

Thus, the programming and erase operations both result in the memory cells 205 being placed in the “0” state. The difference between the operations lies in the biasing level. In the programming operation, a large bias is applied to cause energy-band bending, and therefore Fower-Nordheim tunneling, to occur in the charge trapping structure 228A, thereby trapping electrons in the charge trapping structure 228A. In the erase operation, the applied bias is insufficient to cause energy band bending, which means that formerly trapped electrons do not flow from the charge trapping structure 228A.

A read operation is applicable to both the volatile electromechanical memory cell embodiment of FIGS. 4-6 and the non-volatile electromechanical memory cell embodiment of FIGS. 7-10. In the case of a read operation, the selected read word line coupled to the read electrode 112, 212 is biased with a moderate negative voltage “−”, V_{RWL}, for example of −4V, while the other lines, including the selected write word line coupled to the write electrode 110, 210, the selected bit line coupled to the transition electrode 136, 236 and the unselected bit lines and read and write word lines are placed in a ground state. This results in a voltage difference between the read electrode 112, 212 and the transition electrode 136, 236 to be a positive value; thus the direction of the applied electrostatic force is in a direction from the transition electrode 136, 236 to the read electrode 112, 212, which results in movement of the transition electrode 236 in a direction toward the read electrode 112, 212, depending on the previous state of the gap between the transition electrode 136, 236 and the read electrode 112, 212. If the transition electrode 136, 236 was previously in a data “0” state, that is, in a state of contact with the write electrode 110, 210, then the gap between the transition electrode 136, 236 and the read electrode 112, 212 is relatively large. Thus, the applied electrostatic force between the transition electrode 136, 236 and the read electrode 112, 212, combined with the restoring force of the transition electrode 136, 236, is insufficient for overcoming the attractive Coulomb force between the transition electrode 136, 236 and the write electrode 110, 210. The transition electrode 136, 236 therefore remains in a bent position toward the write electrode 110, 210 during the read operation, as shown in FIGS. 5B and 9B, and no current is sensed, resulting in a determination that the read data element is of value “0”. On the other hand, if the transition electrode 136, 236 was previously in a data “1” state, that is in a state of suspension in the gap between the write electrode 110, 210 and the read electrode 112, 212, then the gap 118B, 218B distance between the transition electrode 136, 236 and the read electrode 112, 212 is relatively small. Thus, the applied electrostatic force between the transition electrode 136, 236 and the read electrode 112, 212 is sufficient for placing the transition electrode 136, 236 in contact with the read electrode 112, 212. The transition electrode 136, 236 is thereby placed in a bent position toward the read electrode 112, 212 during the read operation, as shown in FIGS. 4B and 8B, and current flow is sensed, resulting in a determination that the read data element is of value “1”.

FIG. 3B is a graph of the state of the transition electrode 136, 236 as a function of the applied voltage difference between voltage levels applied to the bit line V_{BL} coupled to the transition electrode 136, 236 and the write word line V_{WWL} coupled to the write electrode 112, 212. When the voltage difference V_{BL}−V_{WWL} is positive by a sufficient amount, the transition electrode 136, 236 moves to deflect in a direction toward the write electrode 110, 210, and thus the gap Tgap between the transition electrode 136, 236 and the write electrode 110, 210 becomes zero. The applied voltage that is sufficient to cause this action is referred to in FIG. 3B as the “pull-in” voltage or Vpull-in. In contrast, when the voltage difference V_{BL}−V_{WWL} is negative by a sufficient amount, the transition electrode 136, 236 moves to deflect in a direction toward the read electrode 112, 212, and thus the gap Tgap between the transition electrode 136, 236 and the write electrode 112, 212 is present. The applied voltage that is sufficient to cause this action is referred to in FIG. 3B as the “pull-out” voltage or Vpull-out. In the graph of FIG. 3B, Vpull-in=V_{BL}−V_{WWL}>0, while Vpull-out=V_{BL}−V_{WWL}<0. Note that this chart applies to the non-volatile electromechanical memory device example of FIGS. 7-10, including the charge trapping structure 228a. Absent the charge trapping structure 228a, for example, in the volatile electromechanical memory device embodiment of FIGS. 2 and 4-6, Vpull-out will lie at zero voltage or at a small, positive voltage.

In each state of “0” and “1”, a Coulomb (or capacitive) force is present between oppositely biased electrodes, and a recovery force, or restoring force, is present in the natural propensity of the transition electrode 136, 236 to restore itself to the rest position. This recovery force is related to the Young's modulus of the transition electrode material, among other factors.

FIGS. 4A and 4B are perspective views of a memory cell 105 in a first state and a read operation of the memory cell 105 in the first state, respectively, for the volatile electromechanical memory device embodiment of FIG. 2.

Referring to FIG. 4A, as a result of a write operation, the transition electrode 136 is in a rest position, that is, in a suspended position between the write electrode 110 and the read electrode 112, and not engaging either the write electrode 110 or the read electrode 112. To reach this state, absent the strong biasing voltage between the transition electrode 136 and the write electrode 110, the restoring force of the transition electrode 136 operates to overcome the Coulomb force between the transition electrode 136 and the write electrode 110. Accordingly, the transition electrode 136 is in the rest position. In one embodiment, this position of the transition electrode 136 corresponds with a “1” binary state for the memory cell 105; however, in another embodiment, the transition electrode 136 being in such a rest position could equally be considered to correspond with a “0” binary state for the memory cell 105.

In the state of “1” as shown in FIG. 4A, the transition electrode 136 is positioned at a suitable gap distance from the read electrode 112 and remains in that position until a subsequent write or read operation occurs. During a subsequent read operation of the memory cell 105, a voltage potential is applied between the read electrode 112 and the transition electrode 136 that is sufficient in magnitude to cause the transition electrode 136 to deflect from the rest position of FIG. 4A to an engaged position as shown in FIG. 4B, whereby the transition electrode 136 is bent in a direction through the second gap 118B and such that the transition electrode 136 makes contact with a side surface of the read electrode 112. The suspended transition electrode 136 is pulled in a direction toward the read electrode 112 by the present attractive Coulomb force between the transition electrode 136 and the read electrode 112, until they are engaged. In this engaged position, a current is generated between the read word line connected to the read electrode 112 and the bit line connected to the transition electrode 136. The current is sensed by current sensing circuitry connected to the read word line of the device, which results in the read operation indicating a reading of a “1” state for the memory cell 105.

FIGS. 5A and 5B are perspective views of a memory cell 105 in a second state and a read operation of the memory cell 105 in the second state, respectively, for the volatile electromechanical memory device embodiment of FIG. 2.

Referring to FIG. 5A, as a result of a write operation, the transition electrode 136 is in an engaged position, whereby the transition electrode 136 is bent in a direction to make contact with a side surface of the write electrode 110. To reach this state, when the transition electrode 136 is positively biased and the write electrode 110 is negatively biased, such as during a write operation, the transition electrode 136 is bent in a direction to contact the write electrode 110 because the Coulomb force present as a result of the bias overcomes the restoring force of the transition electrode 136. In the non-volatile embodiment of FIGS. 7-10 below, when the bias is later removed, for example, when power is removed from the device, the transition electrode 236 remains in the bent position, in contact with the write electrode 210, because the Coulomb force is maintained by the electrons trapped in the charge trapping structure 228 below the write electrode 210. In one embodiment, this position of the transition electrode corresponds with a “0” binary state for the memory cell 105; however, in another embodiment, the transition electrode being in such a bent position could equally be considered to correspond with a “1” binary state for the memory cell 105.

In the state of “0” as shown in FIG. 5A, the transition electrode 136 is bent so that it makes contact with a side surface of the write electrode 110 and remains in that position, until a subsequent write or read operation occurs. During a subsequent read operation of the memory cell 105, a voltage potential is applied between the read electrode 112 and the transition electrode 136. A voltage potential for the read operation is selected as one that would have been sufficient in magnitude to cause the transition electrode 136 to deflect from the rest position of FIG. 4A to an engaged position with the side surface of the read electrode 112; however, the relatively small voltage potential applied between the read electrode 112 and the transition electrode 136 for the read operation combined with the restoring force of the transition electrode 136 is not of sufficient magnitude so as to overcome the attractive Coulomb force between the write electrode 110 and the transition electrode 136. As a result, during a read operation of the memory cell 105 in the state shown in FIG. 5A, the transition electrode 136 remains in the same position, that is, in an engaged position with the side surface of the write electrode 110. Thus, during the read operation, when the read operation voltage potential is applied to the read electrode 112 and the transition electrode 136, no current is generated between the read word line connected to the read electrode 112 and the bit line connected to the transition electrode 136, because the transition electrode 136 in the bent position does not operate to close the current path between the read electrode 112 and the transition electrode 136. The lack of current, as detected by the corresponding current sensing circuitry connected to the read word line of the device, results in the read operation indicating a reading of a “0” state for the memory cell 105.

In the non-volatile memory cell embodiment of FIGS. 7-10 below, upon initial programming of the device, the high-bias condition provides the charge trapping structure 228A with tunneling of electrons, through Fower-Nordheim tunneling. No further programming is required since the trapped electrons permanently occupy the charge trapping structure 228A; thus, no further high-bias operation is needed. Transition between the “1” and “0” states is achieved by moderate biasing of the write electrode 210 and the transition electrode 236; a moderate bias level that does not result in further Fower-Nordheim tunneling. As a result, the device is operable at moderate power levels, leading to high energy efficiency.

To ensure accurate and reliable programming, erase, writing and reading operations in a device, the elasticity of the transition electrode 136, 236 the widths of the first and second gaps 118A, 118B, 218A, 218B and the magnitude and polarity of the applied voltages are considered. For example, the elasticity of the transition electrode 136, 236 is dependent at least in part, on the length and thickness of the transition electrode 136, 236 and the material properties of the transition electrode 136, 236. The first and second gap widths 118A, 118B, 218A, 218B or distances, affect on the amount of travel of the transition electrode 136 between a position of engagement with the read electrode 112, 212 a rest position, and a position of engagement with the write electrode 110, 210. The gap distances affect the voltage levels that are required for moving the transition electrode 136, 236 between its various engaging and rest positions. The first and second gap distances 118A, 118B, 218A, 218B can be the same, or different, depending on the application. Elasticity of the transition electrode 136, 236 material affects the resilience of the transition electrode 136, 236 and its propensity to return to the rest position, as well as the lifespan of the transition electrode 136, 236 over many cycles of write and read operations. In addition, since the transition electrode 136, 236 is coupled only at its first end 135A, 235A, while its second end 135B, 235B is freely moveable, this provides increased flexibility in the transition electrode 136, 236, and reduced operating voltage in the resulting device. Tradeoffs between each of these factors, and other factors, will contribute to the operating speed, operating voltages, and reliability of the resulting device.

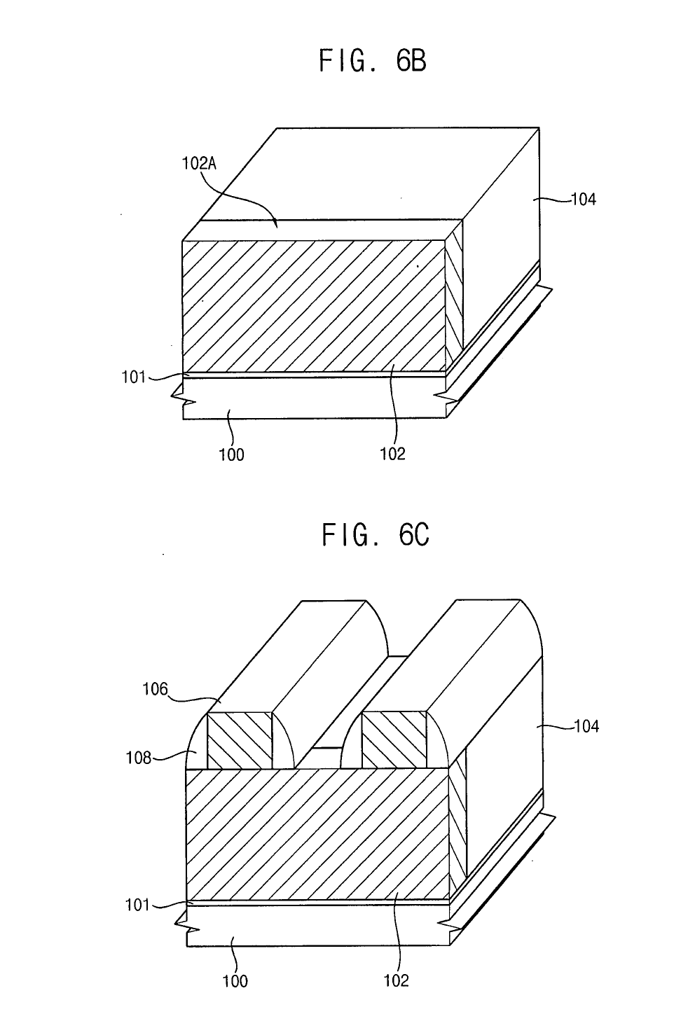

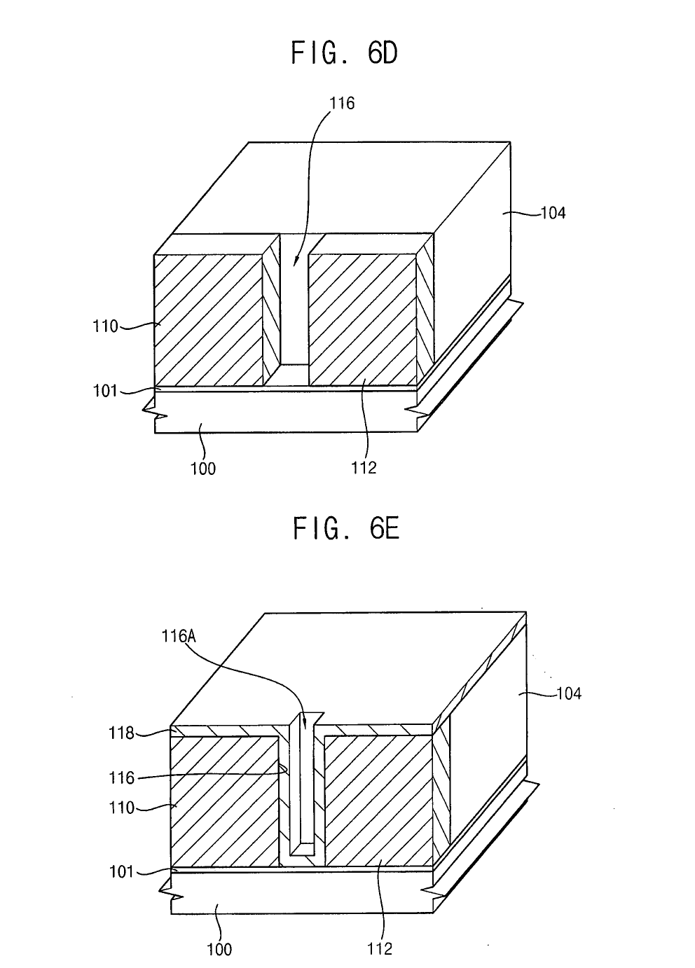

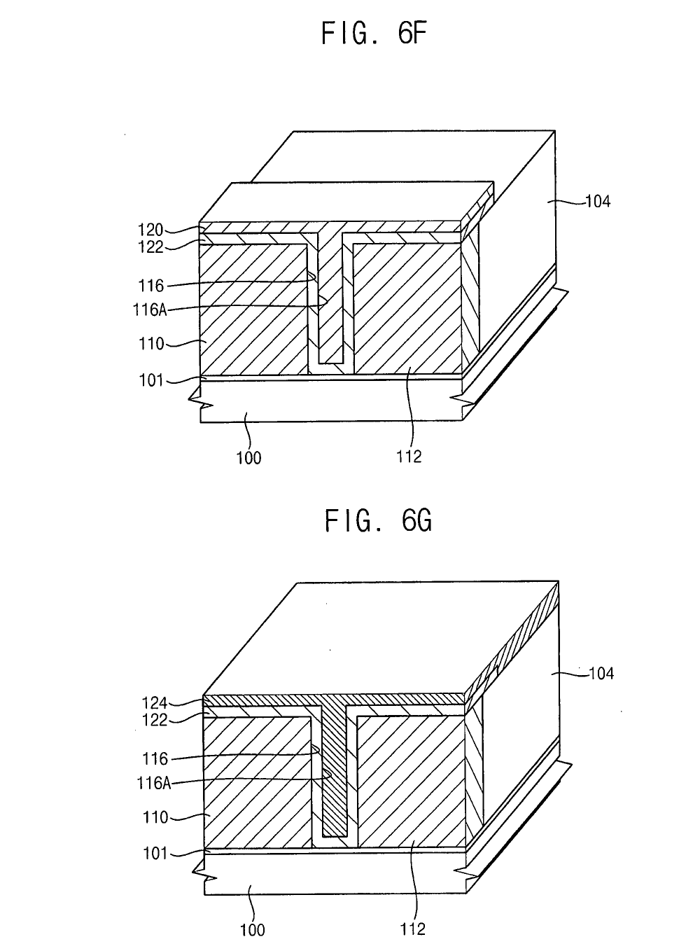

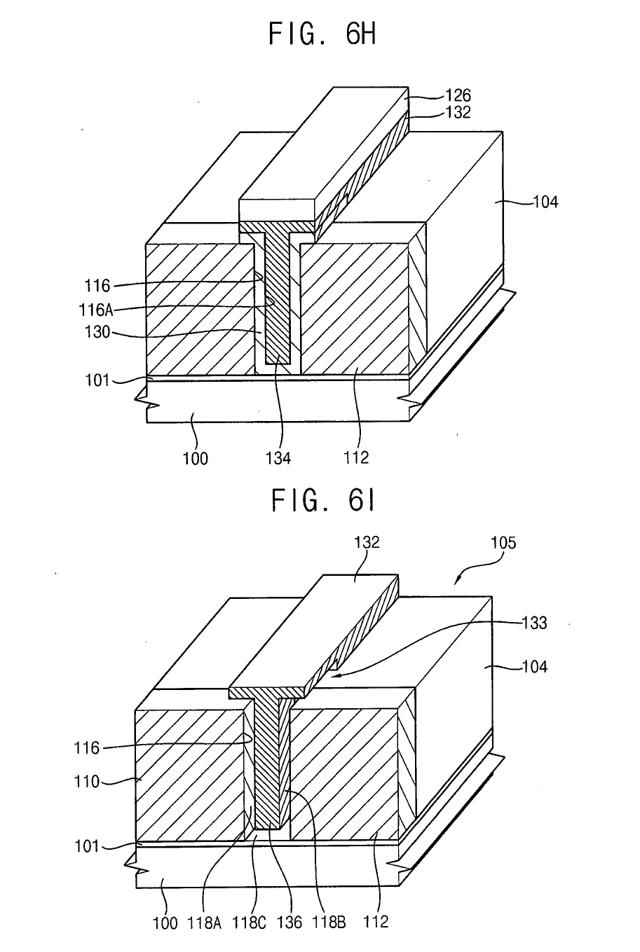

FIGS. 6A-6I are perspective views of a method for forming a volatile electromechanical memory device in accordance with an embodiment of the present invention.

Referring to FIG. 6A, a first insulating layer 101, for example comprising silicon oxide, is provided on a substrate 100. The substrate 100 can comprise, for example, a semiconductor material, such as bulk silicon. Alternatively, the substrate 100 can comprise a silicon-on-insulator (SOI) structure or a flexible insulation layer that is applied to an underlying bulk structure for support. If the substrate 100 is itself formed of an insulating material, then, in certain embodiments, the first insulating layer 101 may not be necessary.

A first preliminary electrode layer is formed and patterned on the substrate 100 using standard photolithographic techniques so as to form a monolithic first preliminary electrode structure 102. The height of the preliminary electrode structure 102 corresponds directly to the eventual length of the transition electrode 136, and is therefore selectively determined. The first preliminary electrode layer used to form the preliminary electrode structure 102 can comprise, for example, a conductive material such as gold, silver, copper, aluminum, tungsten, titanium nitride, polysilicon or any other suitable conductive material that can be eventually patterned to form the write electrode 110 and read electrode 112 of the cell 105. In one embodiment, the preliminary electrode layer comprises a conductive metal layer, such as WSi₂ or Al, formed to a thickness of about 10 nm-1 μm) using a chemical vapor deposition (CVD) or physical vapor deposition (PVD) process.

Referring to FIG. 6B, a second insulating layer 104 is provided on the resulting structure and substrate and is planarized to a level of the top surface 102A of the preliminary electrode structure 102 so that the second insulating layer 104 is positioned at a side of the preliminary electrode structure 102. In one example, the second insulating layer 104 comprises oxide, formed, for example, using a CVD process, followed by a chemical-mechanical polishing (CMP) process for planarization.

Referring to FIG. 6C, a first hard mask pattern 106 is provided on the resulting structure using standard CVD, photolithography, and etching processes, and sidewall spacers 108 are formed at sidewalls of the first hard mask pattern 106 elements, in accordance with standard fabrication techniques. The resulting spacing between adjacent opposed sidewall spacers 108 defines the width of a resulting trench 1116. The spacing between the sidewall spacers 108 can be adjusted by controlling the etch conditions used for their formation.

Referring to FIG. 6D, a trench 116 is selectively etched in the preliminary electrode structure 102 to expose the first insulating layer 101 or substrate 100 to thereby separate the preliminary electrode structure 102 into first and second electrodes that, in one embodiment, correspond to a write electrode 110 and a read electrode 112 for the memory cell. Use of the sidewall spacers 108 to form the trench 116 allows the trench 116 to be formed to a controlled width, the controlled width being less than the spacing achievable under the resolution limit of the photolithography process used for forming the first hard mask pattern. Following etch of the trench 116, the first hard mask pattern 106 and sidewall spacers 108 are then removed using a selective wet etch procedure.

Referring to FIG. 6E, a sacrificial layer 118 is formed and patterned on the resulting structure, conformally coating the write electrode 110, the read electrode 112, the second insulating layer 104 and inner sidewall and bottom surfaces of the trench 116. The sacrificial layer 118 is formed, for example, of polysilicon, nitride or oxide, using a CVD process, resulting in a spacer-shaped structure on the sidewalls of the trench, formed to a thickness of about 3 nm-50 nm. The sacrificial layer 118 coats, but does not fill, the trench 116, resulting in a reduced-width hole 116A being defined in the trench 116. The thickness of the sacrificial layer 118 defines the inner dimensions of the hole 116A, which will, in turn, define the resulting dimensions of the transition electrode 136 to be later formed in the hole 1116A.

Referring to FIG. 6F, a second hard mask layer is formed and patterned on the resulting structure, the resulting second hard mask pattern 120 filling the hole 116A, and covering a region corresponding to the upper surfaces 102A of the write electrode 110 and read electrode 112, and overlapping an adjacent region of the second insulating layer 104. The second hard mask layer is formed, for example, of nitride, using a CVD process, and is patterned using a standard photolithography process. Exposed portions of the sacrificial layer 122 are then selectively removed using the resulting second hard mask pattern 120 as an etch mask.

Referring to FIG. 6G, the second hard mask pattern 120 is removed from the upper surfaces 102A of the write electrode 110 and read electrode 112 and from the hole 116A using a H₂SO₄ wet etch procedure. Following this, a second electrode layer 124 is applied to the resulting structure, filling the hole 116A. The second electrode layer 124 can comprise, for example, a conductive material such as gold, silver, copper, aluminum, tungsten, titanium nitride, polysilicon or any other suitable conductive material that can be patterned. The second electrode layer 124 can further comprise nanotube structures of the type disclosed in United States Application Publication No. 2004/0181630, incorporated by reference above. In one embodiment, the second electrode layer 124 comprises TiN material, formed to a thickness ranging between about 5 nm and 50 nm, and, in one embodiment, 20 nm, formed using CVD, and is patterned using a polysilicon hard mask that is removed following patterning.

Referring to FIG. 6H, a third hard mask layer is formed and patterned on the resulting structure, to form a third hard mask pattern 126 that extends on the resulting structure in a direction that is transverse to the alignment of the write and read electrodes 110, 112 on opposite sides of the trench 116. The third hard mask pattern 126 is used as a mask to pattern the underlying second electrode layer 124 and first patterned sacrificial layer 122. As a result, a transition electrode terminal 132 is defined, the transition electrode terminal 132 being coupled to the transition electrode 134 in the hole 116A. A third patterned sacrificial layer 130 remains in the trench 116 and on neighboring upper surfaces of the write and read electrodes 110, 112, and the neighboring upper surface of the second insulting layer 104.

Referring to FIG. 6I, the third hard mask pattern 126 is selectively removed from the resulting structure. The third patterned sacrificial layer 130 is also selectively removed using a wet etching process or a chemical dry etch (CDE) process. Assuming the sacrificial layer 130 is formed of polysilicon, a wet etchant including HNO₃, having a high selectivity with the metal materials, can be used. Removal of the third patterned sacrificial layer 130 forms first and second gaps 118A, 118B between the resulting transition electrode 136 and the corresponding write electrode 110 and read electrode 112, and undermines a region below the transition electrode terminal 132 in the region of connection between the transition electrode terminal 132 and the transition electrode 136. As a result, the transition electrode 136 is suspended, and freely moveable, in the trench 116 between the write and read electrodes 110, 112, while the transition electrode 136 and transition electrode terminal 132 are both isolated from the write and read electrodes 110, 112. A first gap 118A is formed between the transition electrode 136 and the write electrode 110 and a second gap 118B is formed between the transition electrode 136 and the read electrode 112. A lower gap 118C is also formed between the transition electrode 136 and an upper surface of the first insulating layer 101 or an upper surface of the substrate 100. In this manner, the thickness of the applied sacrificial layer 118 thus defines the resulting first and second gap distances 118A, 118B, as well as the thickness of the resulting transition electrode 136. Also, the heights of the write and read electrodes 110, 112 define the length of the resulting transition electrode 136.

While volatile embodiments of the electromechanical memory devices and fabrication methods thereof in accordance with the present invention are described above in connection with FIGS. 2 and 4-6, the principles of the present invention are equally applicable to non-volatile memory devices, and fabrication methods thereof. In one illustrative example, FIG. 7 is a perspective view of an electromechanical non-volatile memory device in accordance with an embodiment of the present invention. This embodiment is similar in configuration to the volatile embodiment described above in connection with FIGS. 2 and 4-6; however, in the present embodiment, first and second charge trapping structures 228A, 228B are positioned between the substrate 200 and the write and read electrodes respectively 210, 212 to render the resulting device capable of non-volatile data retention.

With reference to FIG. 7, a unit memory cell 205 includes a first electrode 210 referred to herein as a “write electrode”, a second electrode 212 referred to herein as a “read electrode” and a third electrode 236 referred to herein as a “transition electrode”. The write electrode 210 and read electrode 212 are positioned on a substrate 200, and are each insulated from the substrate 100 by a respective charge trapping structure 228A, 228B. The write electrode 210 and read electrode 212, and the corresponding charge trapping structures 228A, 228B are spaced apart from each other by a trench 216 formed between them.

The charge trapping layer structures 228A, 228B each comprise a suitable charge trapping configuration, including, for example, a multiple layered oxide/nitride/oxide (ONO) structure including a tunnel oxide layer 220A, 220B formed by thermal oxidation, a nitride layer 222A, 222B formed by chemical vapor deposition (CVD) and a blocking oxide layer 224A, 224B, formed by CVD or atomic layer deposition (ALD). Other suitable charge trapping structure materials such as oxide/nitride/alumina (ONA) are equally applicable to the devices and methods of formation of the embodiments of the present invention.

An optional transition layer can be present between the write electrode 210, or read electrode 212, and the corresponding charge trapping layer structure 228A, 228B. The optional transition layer can be applied to maintain suitable properties in the tunnel oxide layer 220.

A second insulating layer 204 is disposed at back sides of the write and read electrodes 210, 212 and charge trapping structures 228A, 228B and a conductive transition electrode terminal 232 is positioned on the second insulating layer 204. The transition electrode terminal 232 is suspended over the trench 216, and is isolated from the write and read electrodes 210, 212 by a recess 233 formed in the transition electrode terminal 232 between an underside of the transition electrode terminal 232 and top surfaces of the write and read electrodes 210, 212.

The transition electrode 236 is suspended in the trench 216 between the write electrode 210 and read electrode 212 and the corresponding charge trapping structures 228A, 228B, and is spaced apart from the write electrode 210 and first charge trapping structure 228A in a horizontal direction by a first gap 218A and spaced apart from the read electrode 212 and second charge trapping structure 228B in a horizontal direction by a second gap 218B. The transition electrode 236 includes a first end 235A that is anchored to, and electrically coupled to, an underside of the transition electrode terminal 232, and includes a second end 235B that is suspended in the trench 216, between the write and read electrodes 210, 212.

In the illustrative embodiment of FIG. 7, the memory cell 205 can be incorporated in a memory cell array of a memory device in which the write electrode 210 is coupled to a write word line of the device, the read electrode 212 is coupled to a read word line of the device and the transition electrode 136 and corresponding transition electrode terminal 232 are coupled to a bit line of the device. Rows of bit lines extend in a first direction on the substrate and columns of read and write word lines extend in a second direction on the substrate, the second direction of extension being transverse to the first direction of extension. In this manner, the bit lines and write and read word lines intersect each other, and each intersection point corresponds with a memory cell 205 of the device.

In one embodiment, unit memory cells 205 neighboring each other in the second direction of extension share a common read word line and write word line, and unit memory cells 205 neighboring each other in the first direction of extension share a common bit line.

In the embodiment depicted in FIG. 7, the transition electrode 236 is suspended in position between the first and second gaps 218A, 218B, between the Write electrode 210 and the read electrode 212, and is formed of an elastically deformable material so as to be movable through the first and second gaps 218A, 218B. By controlling the position of the transition electrode 236 in the gaps 218A, 218B, the transition electrode 236 can be caused to make contact, for example, in an engaged position, with a side surface of the write electrode 210 or with a side surface of the read electrode 212, or can be made to be suspended, for example, in a rest position, between the write and read electrodes 210, 212 and not make contact with either. By controlling the respective voltage levels of the voltages applied to the bit line connected to the transition electrode 236, and applied to the independent write and read word lines connected respectively to the write and read electrodes 210, 212, programming, erase, write, and read operations of each of the memory cells 205 can be performed, as will be described in detail below. For example, by applying a suitable voltage level to the write word line connected to the write electrode 210, and by applying a suitable voltage level to the read word line connected to the read electrode 212, the state of the memory cell 205 can be written to a “1” state or to a “0” state. Later, by applying suitable voltage levels to the bit line connected to the transition electrode 236 and the read word line connected to the read electrode 212, a read operation of the state of the memory cell 205 can be performed, as will be described in detail below.

FIGS. 8A and 8B are perspective views of a memory cell in a first state and a read operation of the memory cell in the first state, for the non-volatile electromechanical memory device embodiment of FIG. 7.

Referring to FIG. 8A, as a result of a write operation, the transition electrode 236 is in a rest position, that is, in a suspended position between the write electrode 210 and the read electrode 212, and not engaging either the write electrode 210 or corresponding first charge trapping structure 228A, or the read electrode 212 or corresponding second charge trapping structure 228B. To reach this state, absent the strong biasing voltage between the transition electrode 236 and the write electrode 210, and absent the Coulomb attraction of the first charge trapping structure 228A, the restoring force of the transition electrode 236 operates to overcome the Coulomb force between the transition electrode 236 and the write electrode 210. Accordingly, the transition electrode 236 is in the rest position. In one embodiment, this position of the transition electrode 136 corresponds with a “1” binary state for the memory cell 205; however, in another embodiment, the transition electrode 236 being in such a rest position could equally be considered to correspond with a “0” binary state for the memory cell 205.

In the state of “1” as shown in FIG. 8A, the transition electrode 236 is positioned at a suitable gap distance from the read electrode 212 and remains in that position, in a non-volatile manner, until a subsequent erase, programming, write or read operation occurs. During a subsequent read operation of the memory cell 205, a voltage potential is applied between the read electrode 212 and the transition electrode 236 that is sufficient in magnitude to cause the transition electrode 236 to deflect from the rest position of FIG. 8A to an engaged position as shown in FIG. 8B, whereby the transition electrode 236 is bent in a direction through the second gap 218B and such that the transition electrode 236 makes contact with a side surface of the read electrode 212. The suspended transition electrode 236 is pulled in a direction toward the read electrode 212 by the present attractive Coulomb force between the transition electrode 236 and the read electrode 212, until they are engaged.

The transition electrode 236 makes contact with the side surface of the read electrode 212 and can make contact with a side surface of the blocking oxide layer 224B of the second charge trapping structure 228B; however, the transition electrode 236 is of a length to avoid contact with the side surface of the nitride layer 222B of the second charge trapping structure 228B, since such contact would operate to remove stored charge from the nitride layer 222B. In one embodiment, the length of the transition electrode 236 is determined by controlling the thickness of the sacrificial layer 118 in the bottom of the trench 116 during fabrication.

In this engaged position, a current is generated between the read word line connected to the read electrode 212 and the bit line connected to the transition electrode 236. The current is sensed by current sensing circuitry connected to the read word line of the device, which results in the read operation indicating a reading of a “1” state for the memory cell 205.

FIGS. 9A and 9B are perspective views of a memory cell in a second state and a read operation of the memory cell in the second state, for the non-volatile electromechanical memory device embodiment of FIG. 7.

Referring to FIG. 9A, as a result of a write operation, the transition electrode 236 is in an engaged position, whereby the transition electrode 236 is bent in a direction to make contact with a side surface of the write electrode 210 and the corresponding blocking oxide layer 224a of the corresponding charge trapping structure 228a. To reach this state, when the transition electrode 236 is positively biased and the write electrode 210 is negatively biased, such as during a write operation, the transition electrode 236 is bent in a direction to contact the write electrode 210 because the Coulomb force present as a result of the bias overcomes the restoring force of the transition electrode 236. When the bias is later removed, for example, when power is removed from the device, the transition electrode 236 remains in the bent position, in contact with the write electrode 210, because the Coulomb force is maintained by the electrons trapped in the charge trapping structure 228 below the write electrode 210.

In this state, the transition electrode 236 makes contact with the side surface of the write electrode 210 and can make contact with a side surface of the blocking oxide layer 224A of the first charge trapping structure 228A; however, the transition electrode 236 is of a length to avoid contact with the side surface of the nitride layer 222A of the first charge trapping structure 228A, since such contact would operate to remove stored charge from the nitride layer 222A. As discussed above, in one embodiment, the length of the transition electrode 236 is determined by controlling the thickness of the sacrificial layer 118 in the bottom of the trench 116 during fabrication.

In one embodiment, this position of the transition electrode 236 corresponds with a “0” binary state for the memory cell 205; however, in another embodiment, the transition electrode 236 being in such a bent position could equally be considered to correspond with a “1” binary state for the memory cell 205.

In the state of “0” as shown in FIG. 9A, the transition electrode 236 is bent so that it makes contact with a side surface of the write electrode 210 and remains in that position, until a subsequent erase, write, or programming operation occurs. During a subsequent read operation of the memory cell 205, a voltage potential is applied between the read electrode 212 and the transition electrode 236. A voltage potential for the read operation is selected as one that would have been sufficient in magnitude to cause the transition electrode 236 to deflect from the rest position of FIG. 8A to an engaged position with the side surface of the read electrode 212; however, the relatively small voltage potential applied between the read electrode 212 and the transition electrode 236 for the read operation, combined with the restoring force of the transition electrode 236, is not of sufficient magnitude so as to overcome the attractive force between the write electrode 210 and the transition electrode 236. As a result, during a read operation of the memory cell 205 in the state shown in FIG. 9A, the transition electrode 236 remains in the same position, that is, in engaged position with the side surface of the write electrode 210. Thus, during the read operation, when the read operation voltage potential is applied to the read electrode 212 and the transition electrode 236, no current is generated between the read word line connected to the read electrode 212 and the bit line connected to the transition electrode 136, because the transition electrode 236 in the bent position does not operate to close the current path between the read electrode 212 and the transition electrode 236. The lack of current, as detected by the corresponding current sensing circuitry connected to the read word line of the device, results in the read operation indicating a reading of a “0” state for the memory cell 205. Upon initial programming of the device, the high-bias condition provides the charge trapping structure 228A with tunneling of electrons, through Fower-Nordheim tunneling. No further programming is required since the trapped electrons permanently occupy the charge trapping structure 228A; thus, no further high-bias operation is needed. Transition between the “1” and “0” states is achieved by moderate biasing of the write electrode 210 and the transition electrode 236; a moderate bias level that does not result in further Fower-Nordheim tunneling. As a result, the device is operable at moderate power levels, leading to high energy efficiency.

FIG. 10 is a perspective view of a method for forming a non-volatile electromechanical memory device in accordance with an embodiment of the present invention.

Referring to FIG. 10, a charge trapping layer 228 is provided on a substrate 200. The substrate 200 can comprise, for example, a semiconductor material, such as bulk silicon. Alternatively, the substrate 200 can comprise a silicon-on-insulator (SOI) structure or a flexible insulation layer that is applied to an underlying bulk structure for support.

A first preliminary electrode layer is formed and patterned on the charge trapping layer 228 using standard photolithographic techniques so as to form a monolithic first preliminary electrode structure 202. The height of the preliminary electrode structure 202 corresponds directly to the eventual length of the transition electrode 236, and is therefore selectively determined. In one embodiment, the preliminary electrode structure 202 and the underlying charge trapping layer 228 are patterned at the same time, using the same photomask. In one embodiment, the charge trapping layer 228 comprises oxide/nitride/oxide (ONO) layers formed to respective thicknesses of about 10 nm/20 nm/10 nm. In one embodiment, the ONO layer includes a tunnel oxide layer 220 formed by thermal oxidation, a nitride layer 222 formed by chemical vapor deposition (CVD) and a blocking oxide layer 224 formed by CVD or atomic layer deposition (ALD). Other suitable charge trapping structure materials such as oxide/nitride/alumina (ONA) are equally applicable to the devices and methods of formation of the embodiments of the present invention.

The remaining steps for forming the non-volatile memory device in accordance with the present method illustrated in FIG. 10, and resulting, for example, in the non-volatile electromechanical memory device embodiment illustrated in FIGS. 7-9, are similar to the steps shown above in FIGS. 6A-6I for forming the volatile memory device embodiment, and therefore are not repeated in the description of the present embodiment.

FIG. 11 is a perspective sectional view of a stacked memory device wherein a layer of memory devices are formed on an underlying device layer. A device layer 301 includes a substrate 300, on which is formed a conventional transistor device 303. The conventional transistor device 303 includes a gate structure comprising a gate oxide 302, a polysilicon gate 304 and a gate capping layer 306. Insulative spacers 308 are formed at sidewalls of the gate structure 307, and source and drain regions 310 for the transistor are formed in the substrate extending from the sidewalls of the gate structure 307. An interlayer dielectric layer 312 is formed on the resulting structure and serves as a base for the applied memory cell layer 305.

A memory cell layer 305, including a memory cell, in this example comprising a non-volatile electromechanical memory cell in accordance with that described in connection with FIGS. 7-10 above, is applied to the resulting structure. The memory cell is formed in accordance with the method described above in connection with FIG. 10 and FIGS. 6B-6I. Additional device layers and/or memory cell layers can be formed above or below or between the device layer 301 and memory cell layer 305 shown in FIG. 10. The additional memory cell layers can include non-volatile electromechanical memory cells or volatile electromechanical memory cells, depending on the desired application of the device. In this manner, multiple-layered memory devices, or stacked memory devices, can be formed, including a device layer and at least one electromechanical memory cell layer. The at least one electromechanical memory cell layer can comprise non-volatile electromechanical memory cells, volatile electromechanical memory cells, or multiple layers of both non-volatile electromechanical memory cells and volatile electromechanical memory cells.

FIG. 12 is a perspective view of a non-volatile electromechanical memory device array in accordance with an embodiment of the present invention. In this embodiment, an array of memory cells 405 are arranged to extend in a first direction and in a second direction on the substrate 400. With reference to FIG. 12, a unit memory cell 405 of the array includes a first electrode 426a referred to herein as a “write electrode”, a second electrode 426b referred to herein as a “read electrode” and a third electrode 438A referred to herein as a “transition electrode”. The write electrode 426a and read electrode 426b are positioned on a substrate 400, and are each insulated from the substrate 400 by a respective charge trapping structure 428a, 428b. The write electrode 426a and read electrode 426b, and the corresponding charge trapping structures 428a, 428b are spaced apart from each other by a trench 430A formed between them.

The charge trapping layer structures 428a, 428b each comprise a suitable charge trapping configuration, including, for example, a multiple layered oxide/nitride/oxide (ONO) structure including a tunnel oxide layer 420a, 420b, a nitride layer 422a, 422b, and a blocking oxide layer 424a, 424b, formed as described above in connection with the embodiment of FIG. 7. Other suitable charge trapping structure materials such as oxide/nitride/alumina (ONA) are equally applicable to the devices and methods of formation of the embodiments of the present invention.

A second insulating layer 412 is disposed at back sides of the write and read electrodes 426a, 426b and charge trapping structures 428a, 428b and a conductive transition electrode terminal 438A is positioned on the second insulating layer 412. The transition electrode terminal 438A is suspended over the trench 430A, and is isolated from the write and read electrodes 426a, 426b by a recess formed in the transition electrode terminal between an underside of the transition electrode terminal and top surfaces of the write and read electrodes 426a, 426b, as described above in connection with the embodiments of FIGS. 2 and 7.

The transition electrode 438A, 438B is suspended in the trench 430A, 430B in the same manner described above in connection with FIG. 2 for the volatile embodiment and FIG. 7 for the non-volatile embodiment. A third insulating layer 440 is applied to a top of the resulting structure and conductive plugs 442 are provided to make contact with the write electrodes 426a, 426c, and conductive plugs 444 are provided to make contact with the read electrodes 426b. Write word lines 448A, 448B are positioned on the third insulating layer 440 and extend in a first direction of extension 501. The write word lines 448A, 448B make contact with the underlying write electrodes 426a, 426c using the corresponding plugs 442. Read word lines 446A, 446B are also positioned on the third insulating layer 440 and extend in the first direction of extension 501. The read word lines 446A, 446B make contact with the underlying read electrodes 426b using the corresponding plugs 444.

In the illustrative embodiment of FIG. 7, the memory cells 205 are incorporated in a memory cell array of a memory device. The memory cells are arranged in first and second horizontal directions 501, 503 on the substrate as shown. In the first direction, 501, each neighboring memory cell 405 includes a first write electrode 426a, a shared read electrode 426b and a second write electrode 426c. The shared read electrode 426 is shared by the first and second write electrodes 426a, 426c, and corresponding first and second transition electrodes 438A, 438B to provide a dual-bit configuration. Neighboring memory cells 405 in the second direction are isolated from each other by the second insulating layer 412.

In the array shown in FIG. 12, the first write electrode 426a is coupled to a write word line 448A of the device, the read electrode 426b is coupled to a read word line 446B of the device, the first transition electrode 438A is coupled to a first bit line 436A of the device, and the second transition electrode 438B is coupled to a second bit line 436B of the device. Rows of bit lines 436A, 436B extend in the second direction 503 on the substrate 400 and columns of read and write word lines 446A, 446B extend in the first direction 501 on the substrate, the second direction of extension being transverse to the first direction of extension. In this manner, the bit lines 436A, 436B and write and read word lines 446A, 448A, 446B, 448B intersect each other, and each intersection point corresponds with a memory cell 405 of the device. Unit memory cells 405 neighboring each other in the first direction of extension 501 share a common read word line 446A and write word line 448A, and unit memory cells 405 neighboring each other in the second direction of extension 503 share a common bit line 436A, 436B.

As in the embodiments described above, in the embodiment depicted in FIG. 12, the positions of the transition electrodes 438A, 438B can be controlled to make contact, for example, in an engaged position, with side surfaces of the first and second write electrodes 426a, 426c or with a side surface of the read electrode 426b, or can be made to be suspended, for example, in a rest position, in the trenches 430A, 430B, between the write and read electrodes 426a, 426b, 426c and not make contact with either. By controlling the respective voltage levels of the voltages applied to the bit lines 436A, 436B connected to the transition electrodes 438A, 438B, and applied to the independent write and read word lines 448A, 448B, 446A, 446B connected respectively to the write and read electrodes 426a, 426b, 426c, programming, erase, write, and read operations of each of the memory cells 405 can be performed, as described above.

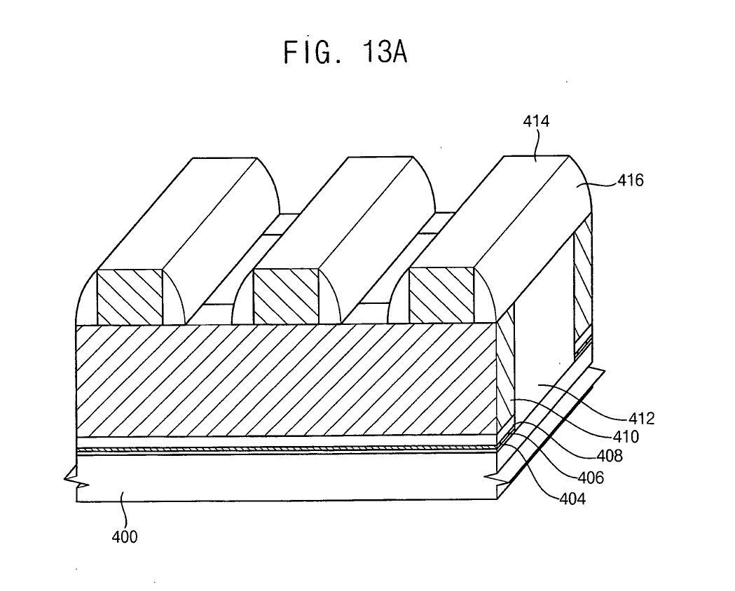

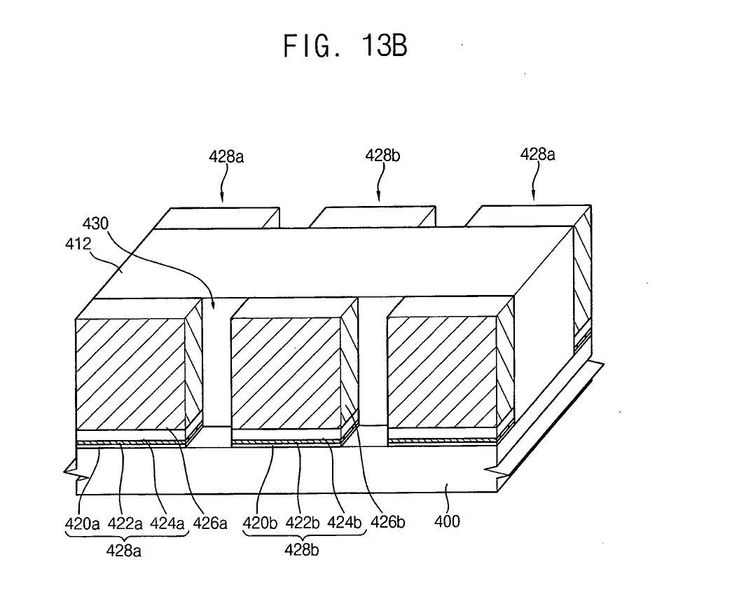

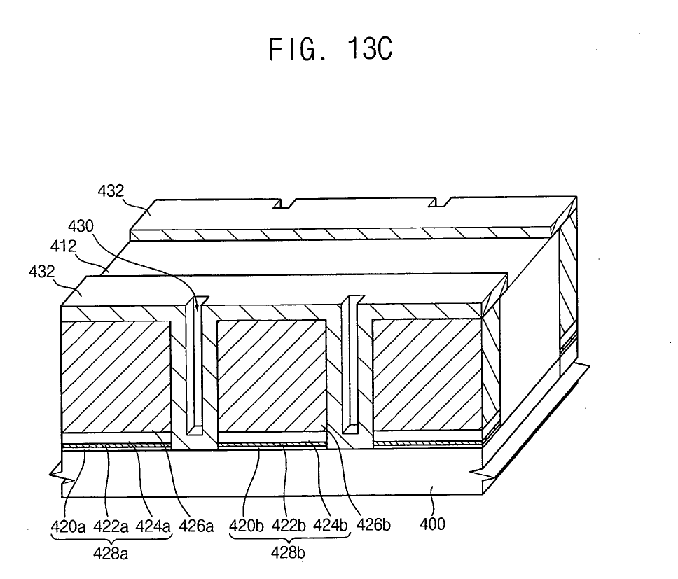

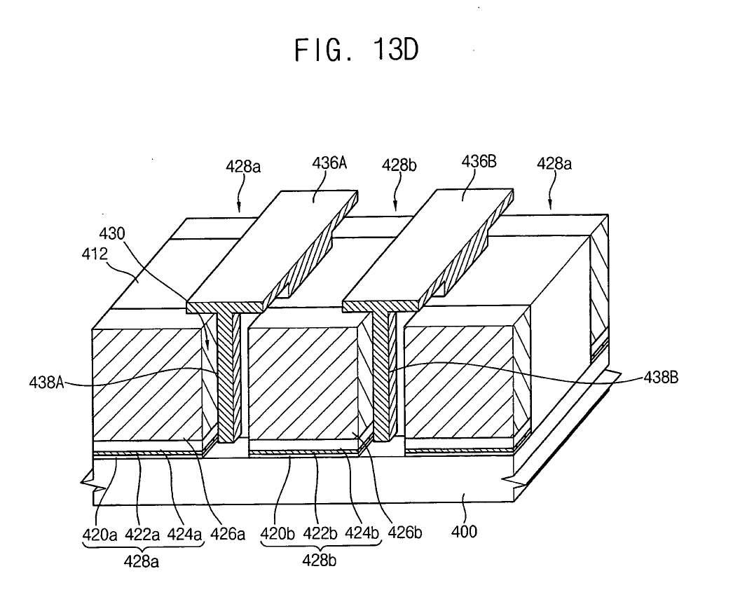

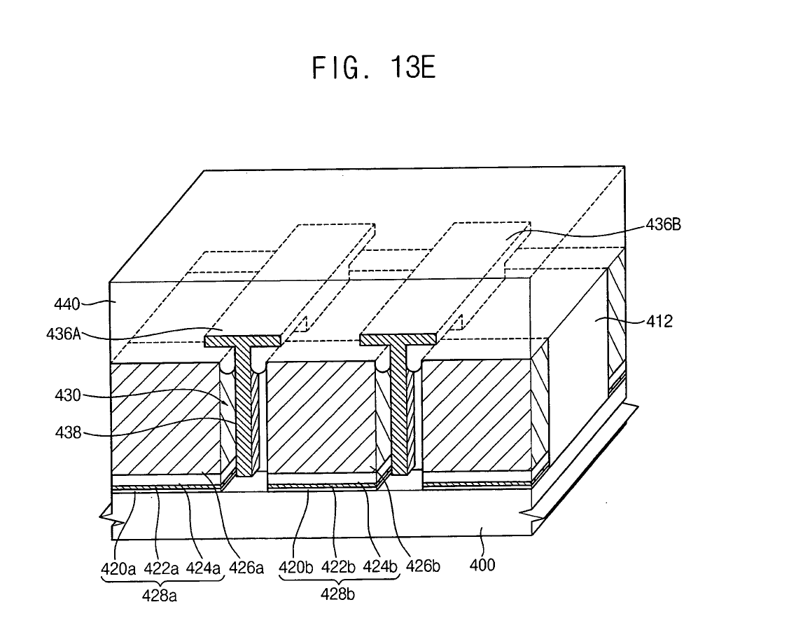

FIGS. 13A-13E are perspective views of a method for forming a non-volatile electromechanical memory device array of the type shown in FIG. 12, in accordance with an embodiment of the present invention.

Referring to FIG. 13A, a charge trapping layer 404, 406, 408 is provided on a substrate 400. The substrate 400 can comprise, for example, any of the materials described above, or other substrate material, suitable for forming a device substrate.

A first preliminary electrode layer is formed and patterned on the charge trapping layer using standard photolithographic techniques so as to form an array of monolithic first preliminary electrode structures 410, each extending in the first direction 501, as described above in connection with FIGS. 10 and 6A. Second isolating layers 412 are positioned between each first preliminary electrode structure 410. First hard mask patterns 414 and sidewall spacers 416 are provided on the resulting structure, the patterns extending in the second direction of extension, in the manner described above in connection with FIG. 6C.

Referring to FIG. 13B, trenches 430 are selectively etched in the preliminary electrode structures, in the manner described above in connection with FIG. 6D. In this manner, isolated write and read electrodes 428a, 428b are formed from the preliminary electrode structures.

Referring to FIG. 13C, a sacrificial layer 432 is formed and patterned on the resulting structure, resulting in reduced-width holes 430 being formed in the trenches, in the manner described above in connection with FIG. 6E.

Referring to FIG. 13D, the steps described above in connection with FIGS. 6F, 6G, 6H, and 6I are performed, resulting in formation of the transition electrodes 438A, 438B and corresponding bit lines 436A, 436B.

Referring to FIG. 13E, a third insulating layer 440 is formed on the resulting structure, for example using a CVD and CMP process. Following this, read and write word lines 446A, 446B, 448, 448B are formed and patterned on the third insulating layer in electrical connection with the underlying read and write electrodes 426b, 426a, 426c using inter-level plugs 444, 442, resulting in the memory device array structure illustrated and described above in connection with FIG. 12

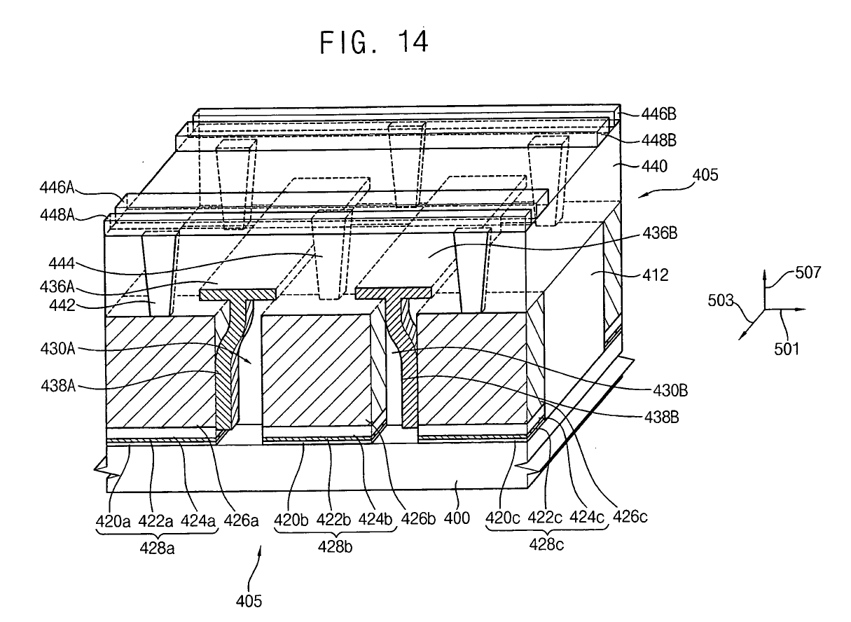

FIG. 14 is a perspective view of memory cells of the non-volatile electromechanical memory device array of FIG. 12 written to contain state information, in accordance with an embodiment of the present invention. In this example, the first transition electrode 438A is in an engaged position with the first write electrode 426a, as a result of a write operation. This corresponds with a state of “0” as described above in connection with the embodiment of FIGS. 9A and 9B. Also, in this example, the second transition electrode 438B is in an engaged position with the second write electrode 426c, as a result of a write operation. This also corresponds with a state of “0” as described above in connection with the embodiment of FIGS. 9A and 9B. The read electrode 426 can be used to read the states of the first and second transition electrodes 438A, 438B that share the read electrode, one at a time, thereby providing for two bits of information, in this case “0” and “0”, using a single read electrode.

In other embodiments, read and write electrode pairs, each pair having a dedicated, corresponding, transition electrode, can be configured to store a bit of information so that each bit state can be accessed independently.

In this manner, embodiments are described above that are directed to electromechanical memory devices and methods of manufacture thereof that address and alleviate the above-identified limitations of conventional devices. In particular, embodiments of the present invention provide electromechanical memory devices that realize, among other features, high-density storage, low-voltage program and erase voltages, high-speed operation, enhanced data retention, and high long-term endurance, and methods of formation of such devices. The embodiments of the present invention are applicable to both non-volatile and volatile memory device formats, and can be configured in a stacked arrangement and in an array of devices.

While embodiments of the invention have been particularly shown and described with references to preferred embodiments thereof, it will be understood by those skilled in the art that various changes in form and details may be made herein without departing from the spirit and scope of the invention as defined by the appended claims.

What is claimed is:

1. A memory device comprising:
a substrate;
a first electrode extending in a vertical direction relative to the substrate;
a second electrode extending in a vertical direction relative to the substrate, the second electrode being spaced apart from the first electrode by a vertical gap; and
a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

2. The memory device of claim 1 wherein the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

3. The memory device of claim 1 wherein the first electrode is coupled to a first word line of the device and wherein the second electrode is coupled to a second word line of the device, and wherein the third electrode is coupled to a bit line of the device.

4. The memory device of claim 3 wherein the first word line comprises a write word line of the device and wherein the second word line comprises a read word line of the device.

5. The memory device of claim 1 wherein the third electrode comprises an elastically deformable material.

6. The memory device of claim 5 wherein the third electrode comprises at least one material selected from the group consisting of: gold, silver, copper, aluminum, tungsten, TiN, conductive metal, shaped memory alloy, and nanotubes.

7. The memory device of claim 1 wherein the first electrode and second electrode each comprise a conductor, and wherein the memory device comprises a volatile memory device.

8. The memory device of claim 1 further comprising a charge trapping structure between the substrate and the first electrode, and wherein the memory device comprises a non-volatile memory device.

9. The memory device of claim 8 wherein in the first bent position, the third electrode is capacitively coupled to the charge trapping structure of the first electrode.

10. The memory device of claim 8 wherein the charge trapping structure comprises a structure selected from the group consisting of: an oxide-nitride-oxide (ONO) structure and an oxide-nitride-alumina (ONA) structure.

11. The memory device of claim 8 wherein the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

12. The memory device of claim 111 wherein during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

13. The memory device of claim 12 wherein during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

14. The memory device of claim 11 wherein during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

15. The memory device of claim 14 wherein during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

16. A method of forming a memory device comprising:
providing a first electrode extending in a vertical direction relative to a substrate;
providing a second electrode extending in a vertical direction relative to the substrate, the second electrode being spaced apart from the first electrode by a vertical gap; and
providing a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

17. The method of claim 16 wherein the first and second electrodes are spaced apart from each other by the electrode gap in a first direction, and further comprising providing a dielectric layer adjacent the first and second electrodes in a second direction transverse to the first direction, such that the third electrode is supported by the dielectric layer.

18. The method of claim 16 further comprising coupling the first electrode to a first word line of the device, coupling the second electrode to a second word line of the device, and coupling the third electrode to a bit line of the device.

19. The method of claim 18 wherein the first word line comprises a write word line of the device and wherein the second word line comprises a read word line of the device.

20. The method of claim 16 wherein the third electrode comprises an elastically deformable material.

21. The method of claim 20 wherein the third electrode comprises at least one material selected from the group consisting of: gold, silver, copper, aluminum, tungsten, TiN, conductive metal, shaped memory alloy, and nanotubes.

22. The method of claim 16 wherein the first electrode and second electrode each comprise a conductor, and wherein the memory device comprises a volatile memory device.

23. The method of claim 16 further comprising providing a charge trapping structure between the substrate and the first electrode, and wherein the memory device comprises a non-volatile memory device.

24. The method of claim 23 wherein in the first bent position, the third electrode is capacitively coupled to the charge trapping structure of the first electrode.

25. The method of claim 23 wherein the charge trapping structure comprises a structure selected from the group consisting of: an oxide-nitride-oxide (ONO) structure and an oxide-nitride-alumina (ONA) structure.

26. The method of claim 23 wherein the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

27. The method of claim 26 wherein during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

28. The method of claim 27 wherein during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

29. The method of claim 26 wherein during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

30. The method of claim 29 wherein during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

31. A method of forming a memory device comprising:
providing a first electrode and a second electrode on a substrate, the first and second electrodes being spaced apart by a gap;
providing a sacrificial layer in the gap;
providing a third electrode on the sacrificial layer in the gap, the third electrode being spaced apart from the first and second electrodes by the sacrificial layer; and
removing the sacrificial layer to form a first gap between the third electrode and the first electrode and to form a second gap between the third electrode and the second electrode.

32. The method of claim 31 wherein the third electrode is elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

33. The method of claim 32 further comprising providing a charge trapping structure between the substrate and the first electrode, and wherein the memory device comprises a non-volatile memory device.

34. The method of claim 33 wherein in the first bent position, the third electrode is capacitively coupled to the charge trapping structure of the first electrode.

35. The method of claim 33 wherein the charge trapping structure comprises a structure selected from the group consisting of: an oxide-nitride-oxide (ONO) structure and an oxide-nitride-alumina (ONA) structure.

36. The method of claim 33 wherein the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

37. The method of claim 36 wherein during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

38. The method of claim 37 wherein during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

39. The method of claim 36 wherein during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

40. The method of claim 39 wherein during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

41. The method of claim 31 further comprising coupling the first electrode to a first word line of the device, coupling the second electrode to a second word line of the device, and coupling the third electrode to a bit line of the device.

42. The method of claim 41 wherein the first word line comprises a write word line of the device and wherein the second word line comprises a read word line of the device.

43. The method of claim 31 wherein the third electrode comprises an elastically deformable material.

44. The method of claim 43 wherein the third electrode comprises at least one material selected from the group consisting of: gold, silver, copper, aluminum, tungsten, TiN, conductive metal, shaped memory alloy, and nanotubes.

45. The method of claim 31 wherein the first electrode and second electrode each comprise a conductor, and wherein the memory device comprises a volatile memory device.

46. The method of claim 31 wherein providing the first electrode and the second electrode on the substrate comprises:
providing an electrode layer on the substrate;
providing a dielectric layer on the substrate adjacent the first electrode layer; and
providing a first opening in the first electrode layer to form a first electrode and a second electrode spaced apart by the gap, and wherein the third electrode is supported by the dielectric layer.

47. The method of claim 33 wherein providing the sacrificial layer in the gap reduces the width of the gap, and wherein providing the third electrode on the sacrificial layer in the gap provides the third electrode in the opening having the reduced width so that when the sacrificial layer is removed, the third electrode is spaced apart from the first and second electrodes by the respective first and second gaps.

48. A stacked memory device comprising:
a first device layer including an array of transistor devices; and
a second device layer including an array of memory cells, the first and second device layers being vertically arranged with respect to each other,
wherein the memory cells of the first array each include:
a first electrode extending in a vertical direction relative to a substrate;
a second electrode extending in a vertical direction relative to the substrate, the second electrode being spaced apart from the first electrode by a vertical gap; and
a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

49. The stacked memory device of claim 48 wherein, in each of the memory cells, the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

50. The stacked memory device of claim 48 wherein, in each of the memory cells, the first electrode is coupled to a first word line of the device and wherein the second electrode is coupled to a second word line of the device.

51. The stacked memory device of claim 50 wherein, in each of the memory cells, the third electrode is coupled to a bit line of the device.

52. The stacked memory device of claim 50 wherein, in each of the memory cells, the first word line comprises a write word line of the device and wherein the second word line comprises a read word line of the device.

53. The stacked memory device of claim 48 wherein, in each of the memory cells, the third electrode comprises an elastically deformable material.

54. The stacked memory device of claim 53 wherein, in each of the memory cells, the third electrode comprises at least one material selected from the group consisting of: gold, silver, copper, aluminum, tungsten, TiN, conductive metal, shaped memory alloy, and nanotubes.

55. The stacked memory device of claim 48 wherein, in each of the memory cells, the first electrode and second electrode each comprise a conductor, and wherein the memory cell comprises a volatile memory device.

56. The stacked memory device of claim 48 wherein each of the memory cells further comprises a charge trapping structure between the substrate and the first electrode, and wherein the memory cells each comprise a non-volatile memory device.

57. The stacked memory device of claim 56 wherein, in each of the memory cells, in the first bent position, the third electrode is capacitively coupled to the charge trapping structure of the first electrode.

58. The stacked memory device of claim 56 wherein, in each of the memory cells, the charge trapping structure comprises a structure selected from the group consisting of: an oxide-nitride-oxide (ONO) structure and an oxide-nitride-alumina (ONA) structure.

59. The stacked memory device of claim 56 wherein, in each of the memory cells, the first electrode comprises a write electrode and wherein the second electrode comprises a read electrode, and wherein, during a write operation of the memory cell, the third electrode is placed in one of the bent position in contact with the write electrode and the rest position, by applying a first voltage potential between the write electrode and the third electrode.

60. The stacked memory device of claim 59 wherein, in each of the memory cells, during a write operation of a first state of the memory cell that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

61. The stacked memory device of claim 60 wherein, in each of the memory cells, during a read operation of the memory cell in the first state, a second voltage potential is applied between the third electrode and the read electrode, and wherein the read operation results in the determination of the first state when the third electrode remains in the bent position in contact with the write electrode, despite application of the second voltage potential.

62. The stacked memory device of claim 59 wherein, in each of the memory cells, during a write operation of a second state of the memory cell that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

63. The stacked memory device of claim 62 wherein, in each of the memory cells, during a read operation of the memory cell in the second state, a second voltage potential is applied between the third electrode and the read electrode, and wherein the read operation results in the determination of the second state when the third electrode is placed in a bent position in contact with the read electrode as a result of the applied second voltage potential.

64. The stacked memory device of claim 48 wherein the memory cells of the array are non-volatile memory cells.

65. The stacked memory device of claim 48 wherein the memory cells of the array are volatile memory cells.

66. A non-volatile memory device comprising:
a substrate;
a first charge trapping structure on the substrate;
a first electrode on the first charge trapping structure extending in a vertical direction relative to the substrate;
a second electrode extending in a vertical direction relative to the substrate, the second electrode being spaced apart from the first electrode by a vertical gap; and
a third electrode extending in a vertical direction in the electrode gap, the third electrode being spaced apart from the first electrode by a first gap and the third electrode being spaced apart from the second electrode by a second gap, the third electrode being elastically deformable such that the third electrode deflects to be electrically coupled with the first electrode through the first gap in a first bent position and to be electrically coupled with the second electrode through the second gap in a second bent position, and to be isolated from the first electrode and the second electrode in a rest position.

67. The non-volatile memory device of claim 66 wherein the first and second electrodes are spaced apart from each other by the electrode gap in a first direction, and further comprising a dielectric layer adjacent the first and second electrodes in a second direction transverse to the first direction, and wherein the third electrode is supported by the dielectric layer.

68. The non-volatile memory device of claim 66 wherein the first electrode is coupled to a first word line of the device and wherein the second electrode is coupled to a second word line of the device, and wherein the third electrode is coupled to a bit line of the device.

69. The non-volatile memory device of claim 66 wherein the first word line comprises a write word line of the device and wherein the second word line comprises a read word line of the device.

70. The non-volatile memory device of claim 66 wherein the third electrode comprises an elastically deformable material.

71. The non-volatile memory device of claim 70 wherein the third electrode comprises at least one material selected from the group consisting of: gold, silver, copper, aluminum, tungsten, TiN, conductive metal, shaped memory alloy, and nanotubes.

72. The non-volatile memory device of claim 66 wherein the first electrode and second electrode each comprise a conductor.

73. The non-volatile memory device of claim 66 further comprising a second charge trapping structure between the substrate and the second electrode.

74. The non-volatile memory device of claim 66 wherein in the first bent position, the third electrode is capacitively coupled to the charge trapping structure of the first electrode.

75. The non-volatile memory device of claim 66 wherein the charge trapping structure comprises a structure selected from the group consisting of: an oxide-nitride-oxide (ONO) structure and an oxide-nitride-alumina (ONA) structure.

76. The non-volatile memory device of claim 66 wherein the first electrode comprises a write electrode and wherein the second electrode comprises a read electrode, and wherein, during a write operation of the memory device, the third electrode is placed in one of the bent position in contact with the write electrode and the rest position, by applying a first voltage potential between the write electrode and the third electrode.

77. The non-volatile memory device of claim 76 wherein during a write operation of a first state of the memory device that results in the third electrode being placed in a bent position in contact with the write electrode, the third electrode bends to make contact with the write electrode in the bent position in response to the first voltage potential between the write electrode and the third electrode, and wherein, when the first voltage potential between the write electrode and the third electrode is removed, the third electrode remains in the bent position as a result of charge that is trapped in the charge trapping structure of the write electrode.

78. The non-volatile memory device of claim 77 wherein during a read operation of the memory device in the first state, a second voltage potential is applied between the third electrode and the read electrode, and wherein the read operation results in the determination of the first state when the third electrode remains in the bent position in contact with the write electrode, despite application of the second voltage potential.

79. The non-volatile memory device of claim 76 wherein during a write operation of a second state of the memory device that results in the third electrode being placed in the rest position, the third electrode is isolated from the write electrode in the rest position in response to the first voltage potential between the write electrode and the third electrode, and wherein, when the first voltage potential between the write electrode and the third electrode is removed, the third electrode remains in the rest position.

80. The non-volatile memory device of claim 79 wherein during a read operation of the memory device in the second state, a second voltage potential is applied between the third electrode and the read electrode, and wherein the read operation results in the determination of the second state when the third electrode is placed in a bent position in contact with the read electrode as a result of the applied second voltage potential.

81. A memory device comprising:
a plurality of memory devices, each memory device comprising:
a write electrode extending in a vertical direction relative to the substrate;
a read electrode extending in a vertical direction relative to the substrate, the read electrode being spaced apart from the write electrode by a vertical gap; and
a transition electrode extending in a vertical direction in the electrode gap, the transition electrode being spaced apart from the write electrode by a first gap and the transition electrode being spaced apart from the read electrode by a second gap, the transition electrode being elastically deformable such that the transition electrode deflects to be electrically coupled with the write electrode through the first gap in a first bent position and to be electrically coupled with the read electrode through the second gap in a second bent position, and to be isolated from the write electrode and the read electrode in a rest position;
the plurality of memory devices being arranged in an array along multiple rows in a row direction and along multiple columns in a column direction on the substrate;
a plurality of bit lines, each bit line extending in the column direction on the substrate, the transition electrodes of the memory devices of a same column being coupled to a same one of the bit lines;
a plurality of write word lines, each write word line extending in the row direction on the substrate, the write electrodes of the memory devices of a same row being coupled to a same one of the write word lines; and
a plurality of read word lines, each read word line extending in the row direction on the substrate, the read electrodes of the memory devices of a same row being coupled to a same one of the read word lines.

82. The memory device of claim 81 wherein the write and read electrodes are spaced apart from each other by the electrode gap in a first direction, and further comprising a dielectric layer adjacent the write and read electrodes in a second direction transverse to the first direction, and wherein the transition electrode is supported by the dielectric layer.

83. The memory device of claim 81 wherein the transition electrodes comprise an elastically deformable material.

84. The memory device of claim 83 wherein the transition electrodes comprise at least one material selected from the group consisting of: gold, silver, copper, aluminum, tungsten, TiN, conductive metal, shaped memory alloy, and nanotubes.

85. The memory device of claim 81 wherein the write electrodes and read electrodes each comprise a conductor, and wherein the memory device comprises a volatile memory device.

86. The memory device of claim 81 further comprising charge trapping structure between the substrate and the write electrodes, and wherein the memory device comprises a non-volatile memory device.

87. The memory device of claim 86 wherein in the first bent position, the transition electrodes are capacitively coupled to the charge trapping structures of the first electrodes.

88. The memory device of claim 86 wherein the charge trapping structures comprise a structure selected from the group consisting of: an oxide-nitride-oxide (ONO) structure and an oxide-nitride-alumina (ONA) structure.

89. The memory device of claim 86 wherein, during a write operation of the memory device, the transition electrode is placed in one of the bent position in contact with the write electrode and the rest position, by applying a first voltage potential between the write electrode and the transition electrode.

90. The memory device of claim 89 wherein during a write operation of a first state of the memory device that results in the transition electrode being placed in a bent position in contact with the write electrode, the transition electrode bends to make contact with the write electrode in the bent position in response to the first voltage potential between the write electrode and the transition electrode, and wherein, when the first voltage potential between the write electrode and the transition electrode is removed, the transition electrode remains in the bent position as a result of charge that is trapped in the charge trapping structure of the write electrode.

91. The memory device of claim 90 wherein during a read operation of the memory device in the first state, a second voltage potential is applied between the transition electrode and the read electrode, and wherein the read operation results in the determination of the first state when the transition electrode remains in the bent position in contact with the write electrode, despite application of the second voltage potential.

92. The memory device of claim 89 wherein during a write operation of a second state of the memory device that results in the transition electrode being placed in the rest position, the transition electrode is isolated from the write electrode in the rest position in response to the first voltage potential between the write electrode and the transition electrode, and wherein, when the first voltage potential between the write electrode and the transition electrode is removed, the transition electrode remains in the rest position.

93. The memory device of claim 92 wherein during a read operation of the memory device in the second state, a second voltage potential is applied between the transition electrode and the read electrode, and wherein the read operation results in the determination of the second state when the transition electrode is placed in a bent position in contact with the read electrode as a result of the applied second voltage potential.
